(19) United States
(12) Patent Application Publication
(10) Pub. No.: US 2022/0204800 A1
(43) Pub. Date: Jun. 30, 2022

(54) STABILIZED INK COMPRISING SEMICONDUCTOR PARTICLES AND USES THEREOF

(71) Applicant: NEXDOT, Romainville (FR)

(72) Inventors: Marc POUSTHOMIS, Deuil-La-Barre (FR); Michele D'AMICO, Romainville (FR); Yu-Pu LIN, Versailles (FR); Félix BOUSSOUFI, Paris (FR); Sébastien DREYFUSS, Bourg la Reine (FR); Robin FAIDEAU, Houilles (FR)

(73) Assignee: NEXDOT, Romainville (FR)

(21) Appl. No.: 17/605,736

(22) PCT Filed: Apr. 24, 2020
(86) PCT No.: PCT/EP2020/061557

§ 371 Date: Oct. 22, 2021

(30) Foreign Application Priority Data
Apr. 24, 2019 (EP) 19305524.1
Apr. 24, 2019 (EP) 19305525.8

(51) Int. Cl. C09D 11/52; C09D 11/322; H01L 33/50; C09K 11/02; C09K 11/88; C09K 11/74; C01G 15/00; C01G 9/00

(52) U.S. Cl. CPC C09D 11/52; C09D 11/322; H01L 33/504; C09K 11/02; B82Y 20/00; C09K 11/7492; C01G 15/00; C01G 9/00; C09K 11/883

(57) ABSTRACT

An ink including at least one colloidal dispersion of particles and at least one metal halide binder, wherein the binder is a dissociated salt of metal and halogen. Also, a method for preparing a light-sensitive material, a light-sensitive material obtainable by the method, and a device including at least one light-sensitive material obtainable by the method.

### FIELD OF INVENTION

The present invention relates to an ink comprising particles, such as semiconductor particles, and further comprising a colloidal dispersion of particles and at least one metal halide binder. It further relates to light-sensitive materials and photosensitive films obtained by deposition of the ink of the invention; and to supports, devices, systems and uses thereof comprising said light-sensitive materials or photosensitive films.

### BACKGROUND OF INVENTION

Since the first synthesis of colloidal nanocrystal reported in the early 90's, lots of interest have been devoted to the integration of such nanocrystal into optoelectronic device. Colloidal quantum dots (CQD) offers indeed the promises to build low cost optoelectronic devices thanks to the combination of their ease of process with their stability due to their inorganic nature. Most of the efforts were focused on visible wavelength at the early stage, and the idea to use these nanomaterials for applications such as lightning and bio-imaging rapidly appeared.

In the mid 2000's, materials such as lead chalcogenides (PbS) became popular because of their well-suited band gap to absorb the near infrared part of the solar spectrum. Such nanocrystals were of great interest to address the absorption of the near IR range of wavelength of the sun light for photovoltaic application. It is only later that narrower band gap material with optical properties in the mid infrared have started to be synthetized.

However, the use of colloidal nanocrystals into optoelectronic applications have to compete with existing technology such as Complementary Metal Oxide Semiconductor (CMOS) or Indium Gallium Arsenide (InGaAs) which are far more mature and already cost effective. Nevertheless, nanocrystals may offer some interesting properties to compete with existing technologies in particular in high-value optoelectronic devices like cameras of smartphones and tablets.

Indeed, facial recognition is a key-security system in modern smartphones avoiding unauthorized use of the smartphone. Efficient facial recognition needs a high-quality IR-detector in order to identify with “zero-error” chance the smartphone's user.

Quantum dots (QD) with their high-absorption in the IR range are the ideal candidates for theses applications. Nevertheless, the photoabsorptive film comprising QD must comply with strict specifications.

Indeed, the photoabsorptive film must be industrial processing resistant at high temperature, especially stable between 60 and 250° C. during at least three hours. In addition, the photoabsorptive film must be storage-stable under humidity stress, especially high-humidity conditions (85%) during 4 days at a temperature ranging from 60 to 150° C. Finally, the photoabsorptive film must show the same performances (optical and electrical) at ambient temperature (20° C.-60° C.) even if the final device has undergone thermal treatments at a temperature ranging from 100° C. to 200° C. In particular, the photoabsorptive film must show the same performances (optical and electrical) before and after typical thermal treatment of the final device.

The photoabsorptive must also present a time-reproducible response to a light excitation, especially under the following conditions: stress voltage of 2 V, temperature between 25 and 100° C., under a light-emission ranging from 1 to 100 W/m² during 6 hours. Same time-reproducible answer must be obtained with a light-emission of 60 KW/m² during 120 seconds.

Finally, the photoabsorptive film must be water-stable and oxygen-stable.

As general conditions, an IR detector comprising a QD-based photoabsorptive film must present a high quantum efficiency (higher than 20%, preferably higher than 50%), a low dark current and a fast time response.

In addition, QD are generally applied in the form of an ink which must be stable, i.e. the absorption-spectrum must not vary over time and the ink must not flocculate (especially during one or two months) in standard ambient conditions or at temperatures from −50° C. to 30° C.

Thus, there is a real need for such materials complying with the above specifications.

It is therefore an object of the present invention to provide a material having high-absorption in the IR range and presenting the following advantages in IR sensing devices: high stability, time-reproductible response to a light-excitation, high quantum efficiency, low dark current, and fast time response.

### SUMMARY

The invention relates to an ink comprising:
a) at least one colloidal dispersion of particles, said particles comprising a material of formula

MₓQ_{y}E_{z}A_{w} (I)

wherein:
M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
E is selected from the group consisting of O, S, Se, Te, C, N, P, As, Sb, F, Cl, Br, I, or a mixture thereof; and
A is selected from the group consisting of O, S, Se, Te, C, N, P, As, Sb, F, Cl, Br, I, or a mixture thereof;
x, y, z and w are independently a decimal number from 0 to 5; x, y, z and w are not simultaneously equal to 0; x and y are not simultaneously equal to 0; z and w may not be simultaneously equal to 0; and
b) at least one metal halide binder soluble in the colloidal dispersion a).

In one embodiment, the particles are semiconductor particles. In one embodiment, the semiconductor particles are quantum dots. In one embodiment, the quantum dots are core/shell quantum dots, the core comprising a different material from the shell. In one embodiment, the amount of particles in the ink is ranging from 1 to 40 wt %, based on the total weight of the ink. In one embodiment, the metal halide is selected from the group of ZnX₂, PbX₂, CdX₂, SnX₂, HgX₂, BiX₃, CsPbX₃, CsX, NaX, KX, LiX, HC(NH₂)₂PbX₃, CH₃NH₃PbX₃, or a mixture thereof, wherein X is selected from Cl, Br, I, F or a mixture thereof. In one embodiment, the colloidal dispersion of particles comprises at least one polar solvent selected from the group comprising formamide, dimethylformamide, N-methylformamide, 1,2-dichlorobenzene, 1,2-dichloroethane, 1,4-dichlorobenzene, propylene carbonate and N-methyl-2-pyrrolidone, dimethyl sulfoxide, 2,6 difluoropyridine, N,N dimethylacetamide, γ-butyrolactone, dimethylpropyleneurea, triethylphosphate, trimethylphosphate, dimethylethyleneurea, tetramethylurea, diethylformamide, o-Chloroaniline, dibutylsulfoxide, diethylacetamide, or a mixture thereof. In one embodiment, the colloidal dispersion of particles further comprises at least one solvent and at least one ligand, and wherein:
the amount of particles in the ink is ranging from 1 to 40 wt % based on the total weight of the ink;
the amount of solvent in the ink is ranging from 25 to 97 wt % based on the total weight of the ink;
the amount of ligand in the ink is ranging from 0.1 to 8 wt % based on the total weight of the ink; and
the amount of metal halide binder is ranging from 1 to 60% based on the total weight of the ink.

The invention also relates to a method for preparing a light-sensitive material comprising the steps of:
a) depositing an ink of the invention onto a substrate;
b) annealing deposited ink.

In one embodiment, the deposited ink is annealed at a temperature ranging from 50° C. to 250° C. In one embodiment, the deposited ink is annealed during a period of time ranging from 10 minutes to 5 hours.

The invention also relates to a light-sensitive material obtainable by the method of the invention. In one embodiment, said material is a continuous electrically conductive film comprising particles bound by a metal halide.

The invention also relates to a device comprising at least one light-sensitive material of the invention. In one embodiment, the device comprises:
at least one substrate;
at least one electronic contact layer;
at least one electron transport layer; and
at least one photoactive layer comprising at least one light-sensitive material of the invention;
   wherein said device has a vertical geometry.

### Definitions

In the present invention, the following terms have the following meanings:
“Core” refers to the innermost space within a particle.
“Shell” refers to at least one monolayer of material coating partially or totally a core. Alternatively, or additionally, “shell” refers to at least one monolayer of material coating partially or totally an inner shell. In such case of multi-shell particles, each shell can comprise at least one monolayer of the same or of different material.
“Encapsulate” refers to a material that coats, surrounds, embeds, contains, comprises, wraps, packs, or encloses a plurality of particles.
“Colloidal” refers to a substance in which particles are dispersed, suspended and do not settle, flocculate or aggregate; or would take a very long time to settle appreciably, but are not soluble in said substance.
“Colloidal particles” refers to particles that may be dispersed, suspended and which would not settle, flocculate or aggregate; or would take a very long time to settle appreciably in another substance, typically in an aqueous or organic solvent, and which are not soluble in said substance. “Colloidal particles” does not refer to particles grown on substrate.
“Impermeable” refers to a material that limits or prevents the diffusion of outer molecular species or fluids (liquid or gas) into said material.
“Permeable” refers to a material that allows the diffusion of outer molecular species or fluids (liquid or gas) into said material.
“Outer molecular species or fluids (liquid or gas)” refers to molecular species or fluids (liquid or gas) coming from outside a material or a particle.
“Packing fraction” refers to the volume ratio between the volume filled by an ensemble of objects into a space and the volume of said space. The terms packing fraction, packing density and packing factor are interchangeable in the present invention.
“Loading charge” refers to the mass ratio between the mass of an ensemble of objects comprised in a space and the mass of said space.
“Optically transparent” refers to a material that absorbs less than 10%, 5%, 2.5%, 1%, 0.99%, 0.98%, 0.97%, 0.96%, 0.95%, 0.94%, 0.93%, 0.92%, 0.91%, 0.9%, 0.89%, 0.88%, 0.87%, 0.86%, 0.85%, 0.84%, 0.83%, 0.82%, 0.81%, 0.8%, 0.79%, 0.78%, 0.77%, 0.76%, 0.75%, 0.74%, 0.73%, 0.72%, 0.71%, 0.7%, 0.69%, 0.68%, 0.67%, 0.66%, 0.65%, 0.64%, 0.63%, 0.62%, 0.61%, 0.6%, 0.59%, 0.58%, 0.57%, 0.56%, 0.55%, 0.54%, 0.53%, 0.52%, 0.51%, 0.5%, 0.49%, 0.48%, 0.47%, 0.46%, 0.45%, 0.44%, 0.43%, 0.42%, 0.41%, 0.4%, 0.39%, 0.38%, 0.37%, 0.36%, 0.35%, 0.34%, 0.33%, 0.32%, 0.31%, 0.3%, 0.29%, 0.28%, 0.27%, 0.26%, 0.25%, 0.24%, 0.23%, 0.22%, 0.21%, 0.2%, 0.19%, 0.18%, 0.17%, 0.16%, 0.15%, 0.14%, 0.13%, 0.12%, 0.11%, 0.1%, 0.09%, 0.08%, 0.07%, 0.06%, 0.05%, 0.04%, 0.03%, 0.02%, 0.01%, 0.009%, 0.008%, 0.007%, 0.006%, 0.005%, 0.004%, 0.003%, 0.002%, 0.001%, 0.0009%, 0.0008%, 0.0007%, 0.0006%, 0.0005%, 0.0004%, 0.0003%, 0.0002%, 0.0001%, or 0% of light. This may apply to the visible range of wavelengths and/or infrared range of wavelengths (in particular from 900 nm to 1000 nm or from 1300 nm to 1500 nm).
“Polydisperse” refers to particles or droplets of varied sizes, wherein the size difference is superior or equal to 20%.
“Monodisperse” refers to particles or droplets, wherein the size difference is inferior than 20%, 15%, 10%, preferably 5%.
“Narrow size distribution” refers to a size distribution of a statistical set of particles less than 1%, 2%, 3%, 4%, 5%, 6%, 7%, 8%, 9%, 10%, 15%, 20%, 25%, 30%, 35%, or 40% of the average size.
“Partially” means incomplete. In the case of a ligand exchange, partially means that 5%, 10%, 15%, 20%, 25%, 30%, 35%, 40%, 45%, 50%, 55%, 60%, 65%, 70%, 75%, 80%, 85%, 90%, 95% of the ligands at the surface of a particle have been successfully exchanged.
The terms “film”, “layer” or “sheet” are interchangeable in the present invention.
“Nanoplatelet” refers to a 2D shaped particle, wherein the smallest dimension of said nanoplatelet is smaller than the largest dimension of said nanoplatelet by a factor (aspect ratio) of at least 1.5, at least 2, at least 2.5, at least 3, at least 3.5, at least 4, at least 4.5, or at least 5.
“Intraband” refers to an optical transition, which is actually based on intraband transition within a single band or from a plasmonic absorption.
“ROHS-compliant” refers to a material compliant with Directive 2011/65/EU of the European Parliament and of the Council of 8 Jun. 2011 on the restriction of the use of certain hazardous substances in electrical and electronic equipment.
“Aqueous solvent” is defined as a unique-phase solvent wherein water is the main chemical species in terms of molar ratio and/or in terms of mass and/or in terms of volume in respect to the other chemical species contained in said aqueous solvent. The aqueous solvent includes but is not limited to: water, water mixed with an organic solvent miscible with water such as for example methanol, ethanol, acetone, tetrahydrofuran, n-methylformamide, n,n-dimethylformamide, dimethylsulfoxide or a mixture thereof
“Vapor” refers to a substance in a gaseous state, while said substance is in a liquid or a solid state in standard conditions of pressure and temperature.
“Gas” refers to a substance in a gaseous state in standard conditions of pressure and temperature.
“Standard conditions” refers to the standard conditions of temperature and pressure, i.e., 273.15 K and 10⁵ Pa respectively.
“Valence band”, as used herein, refers to one of the two bands (with the conduction band) closest to the Fermi level, which determines the electrical conductivity of a material. The “valence band” is the highest range of electron energies in which electrons are normally present at absolute zero temperature.
“Conduction band”, as used herein, refers to one of the two bands (with the valence band) closest to the Fermi level, which determines the electrical conductivity of a material. The “Conduction band” is the lowest range of vacant electronic states.
“Band gap”, as used herein, refers to the difference of energy between the top of the valence band and the bottom of the conduction band, i.e., the energy range where no electron states can exist due to the quantization of energy. Electrical conductivity is determined by the susceptibility of electrons to excitation from the valence band to the conduction band.
“Alkyl” refers to any saturated linear or branched hydrocarbon chain, with a number of carbon atom ranging from 1 to 12, preferably from 1 to 6, and more preferably the hydrocarbon chain is selected from methyl, ethyl, propyl, isopropyl, n-butyl, sec-butyl, isobutyl and tert-butyl. The alkyl group may be substituted by a saturated or unsaturated aryl group.
When the suffix “ene” (“alkylene”) is used in conjunction with an alkyl group, this is intended to mean the alkyl group as defined herein having two single bonds as points of attachment to other groups. The term “alkylene” includes methylene, ethylene, methylmethylene, propylene, ethylethylene, and 1,2-dimethylethylene.
“Aryl” refers to a mono- or polycyclic system with a number of carbon atoms ranging from 5 to 20, preferably from 6 to 12, and having one or more aromatic rings (when there are two rings, it is called a biaryl) among which it is possible to cite, without limitation, the phenyl group, the biphenyl group, the 1-naphthyl group, the 2-naphthyl group, the tetrahydronaphthyl group, the indanyl group and the binaphthyl group. The term “aryl” also means any aromatic ring including at least one heteroatom chosen from an oxygen, nitrogen or sulfur atom. The aryl group can be substituted by 1 to 3 substituents chosen independently from one another, among a hydroxyl group, a linear or branched alkyl group comprising 1, 2, 3, 4, 5 or 6 carbon atoms, in particular methyl, ethyl, propyl, butyl, an alkoxy group or a halogen atom, in particular bromine, chlorine and iodine, a nitro group, a cyano group, an azido group, an aldehyde group, a boronato group, a phenyl, CF₃, methylenedioxy, ethylenedioxy, SO₂NRR′, NRR′, COOR (where R and R′ are each independently selected from the group comprising or consisting of H and alkyl), an second aryl group which may be substituted as above. Non-limiting examples of aryl comprise phenyl; biphenylyl; biphenylenyl; 5- or 6-tetralinyl; naphthalen-1- or -2-yl; 4-, 5-, 6 or 7-indenyl; 1-, 2-, 3-, 4- or 5-acenaphtylenyl; 3-, 4- or 5-acenaphtenyl; 1- or 2-pentalenyl; 4- or 5-indanyl; 5-, 6-, 7- or 8-tetrahydronaphthyl; 1,2,3,4-tetrahydronaphthyl; 1,4-dihydronaphthyl; 1-, 2-, 3-, 4- or 5-pyrenyl.
The term “chalcogenide”, as used herein, refers to a chemical compound comprising or consisting of (i) at least one chalcogen anion selected from the group comprising or consisting of O, S, Se, Te, Po, and (ii) at least one or more electropositive element.
“Amine” refers to any group derived from ammoniac NH₃ by substitution of one or more hydrogen atoms with an organic radical.
“Azido” refers to —N₃ group.

### DETAILED DESCRIPTION

The following detailed description will be better understood when read in conjunction with the drawings. For the purpose of illustrating, the ink is shown in the preferred embodiments. It should be understood, however that the application is not limited to the precise arrangements, structures, features, embodiments, and aspect shown.

The present invention relates to an ink comprising:
a) at least one colloidal dispersion of particles, said particles comprising a material of formula

MₓQ_{y}E_{z}A_{w} (I)
wherein:
M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
E is selected from the group consisting of O, S, Se, Te, C, N, P, As, Sb, F, Cl, Br, I, F, or a mixture thereof; and
A is selected from the group consisting of O, S, Se, Te, C, N, P, As, Sb, F, Cl, Br, I, F, or a mixture thereof;
x, y, z and w are independently a decimal number from 0 to 5; x, y, z and w are not simultaneously equal to 0; x and y are not simultaneously equal to 0; z and w may not be simultaneously equal to 0; and
b) at least one metal halide binder soluble in the colloidal dispersion a).

Herein “metal” refers to alkali metals, alkaline earth metals, transition metals and/or post-transition metals.

Herein “binder” refers to any material coating partially or totally the surface of each particle that, upon a thermal treatment, contacts particles together and holds particles together to form a cohesive whole, while preserving the original optical properties of particles. Contrary to the binder, a ligand is not able to bind said particles and preserve the original optical properties of particles.

In other words, the ink comprises at least one particle, at least one ligand, at least one liquid vehicle, and at least one metal-containing precursor. Indeed, the colloidal dispersion of particles comprises a plurality of particles, at least one ligand and at least one liquid vehicle (i.e. at least one solvent).

An ink is defined as a liquid dispersion intended to be deposited onto a substrate and then yield a solid film onto said substrate.

To have a stable colloidal dispersion of particles, use of organic ligands is compulsory. However, such organic ligands have long carbon chains, resulting in a spacing of the particles that prevents electrical continuity in the material obtained from the deposition of the ink on a substrate. As a result, the obtained material will not exhibit a satisfying electrical conductivity. Replacing said long carbon chains ligands by a metal halide binder allowed to obtain an electrical contact between particles, thus an electrical continuity in the obtained material. The metal halide binder forms a very thin layer of metal halide on the surface of the particles, allowing close contact between adjacent particles, thus electrical continuity (see FIG. 2).

The Applicant surprisingly discovered that upon annealing of the deposited ink, said binder may form a thin layer of metal halide on the surface of the particles, thus protecting particles against high temperature deterioration. Therefore, the obtained material exhibits the same performances (optical and electrical) at ambient temperature (20° C.-60° C.) before and after thermal treatments that may occur during the fabrication of an optoelectronic device or during the operation of said device, said thermal treatments being typically in the range 100-200° C.

Thus, the aim of the invention is to provide a conductive ink having good high temperature stability, in particular to provide an ink able to form a conductive film, after deposition and annealing of said ink, having good high temperature stability. “High temperature stability” refers to the capacity of an ink, and/or a film obtained by deposition and annealing of said ink, to keep the same performances (optical and electrical) at ambient temperature (20° C.-60° C.) even if said ink, and/or film, has undergone thermal treatments (typically from 100° C. to 200° C. for 30 minutes to several hours).

Once a high temperature is reached, typically 60° C.-200° C., “High temperature stability” refers to the capacity of an ink, and/or a film obtained by deposition and annealing of said ink, to keep the same performances (optical and electrical) along time at this temperature. Herein, the formulas MₓQ_{y}E_{z}A_{w} (I) and MₓN_{y}E_{z}A_{w} can be used interchangeably.

The metal halide binder is obtained by solubilisation, solvatation or dissociation of a metal halide into the ink.

In one embodiment, the amount of particles in the ink is ranging from 1 to 40 wt %, preferably from 1 to 20 wt %, based on the total weight of the ink.

In this disclosure, particles may be luminescent particles, such as for example, fluorescent particles, or phosphorescent particles.

In one embodiment, particles have an absorption spectrum with at least one absorption peak, wherein said at least one absorption peak has a maximum absorption wavelength ranging from about 750 nm to 1.5 μm. In a specific embodiment, absorption peak has a maximum absorption wavelength ranging from 850 nm to 1000 nm, more preferably from 900 nm to 1000 nm, even more preferably from 925 nm to 975 nm. In another specific embodiment, absorption peak has a maximum absorption wavelength ranging from 1300 nm to 1500 nm.

In one embodiment, particles exhibit an emission spectrum with at least one emission peak, wherein said emission peak has a maximum emission wavelength ranging from about 750 nm to about 2 μm, preferably from 1 to 1.8 μm. In this embodiment, the luminescent particles emit near infra-red, mid-infra-red, or infra-red light.

In one embodiment, particles exhibit emission spectra with at least one emission peak having a full width half maximum (FWHM) in the visible range of wavelengths lower than about 90 nm, about 80 nm, about 70 nm, about 60 nm, about 50 nm, about 40 nm, about 30 nm, about 25 nm, about 20 nm, about 15 nm, or about 10 nm. In other words, particles exhibit emission spectra with at least one emission peak having a full width half maximum (FWHM) in the visible range of wavelengths lower than about 0.40 eV, about 0.35 eV, about 0.30 eV, about 0.25 eV, about 0.22 eV, about 0.17 eV, about 0.13 eV, about 0.10 eV, about 0.08 eV, about 0.06 eV, or about 0.04 eV.

In one embodiment, particles exhibit emission spectra with at least one emission peak having a full width half maximum (FWHM) in the infrared range of wavelengths ranging from 100 nm to 250 nm. In other words, particles exhibit emission spectra with at least one emission peak having a full width half maximum (FWHM) in the infrared range of wavelengths ranging from 0.08 eV to 0.2 eV.

In one embodiment, particles have a photoluminescence quantum yield (PLQY) of at least about 1%, about 5%, about 10%, about 15%, about 20%, about 25%, about 30%, about 40%, about 50%, about 60%, about 70%, about 80%, about 90%, or about 100%.

In a preferred embodiment, particles have a photoluminescence quantum yield (PLQY) ranging from 1 to 20%.

In one embodiment, particles are light-sensitive particles. In particular, particles are light-absorbing particles, or light-emitting particles.

In one embodiment, particles are electrically conductive.

In one embodiment, particles are hydrophobic.

In one embodiment, particles are semiconductor particles. In a specific embodiment, particles are semiconductor nanoparticles.

In one embodiment, particles are semiconductor nanocrystals, such as for example quantum dots.

In particular, particles may comprise a material of formula MₓE_{y}, in which M is Zn, Cd, Hg, Cu, Ag, Al, Ga, In, Si, Ge, Pb, Sb or a mixture thereof and E is O, S, Se, Te, N, P, As or a mixture thereof x and y are independently a decimal number from 0 to 5, with the proviso that x and y are not 0 at the same time.

In one embodiment, the particles comprise a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or mixture thereof.

In a specific embodiment, particles comprise a material selected from the group consisting of CdS, CdSe, CdTe, ZnS, ZnSe, ZnTe, HgS, HgSe, HgTe, HgO, GeS, GeSe, GeTe, SnS, SnSe, SnTe, PbS, PbSe, PbTe, GeS₂, GeSe₂, SnS₂, SnSe₂, CuInS₂, CuInSe₂, AgInS₂, AgInSe₂, CuS, Cu₂S, Ag₂S, Ag₂Se, Ag₂Te, FeS, FeS₂, InP, Cd₃P₂, Zn₃P₂, CdO, ZnO, FeO, Fe₂O₃, Fe₃O₄, Al₂O₃, TiO₂, MgO, MgS, MgSe, MgTe, AlN, AlP, AlAs, AlSb, GaN, GaP, GaAs, GaSb, InN, InP, InAs, InSb, TlN, TlP, TlAs, TlSb, MoS₂, PdS, Pd₄S, WS₂, CsPbCl₃, PbBr₃, CsPbBr₃, CH₃NH₃PbI₃, CH₃NH₃PbCl₃, CH₃NH₃PbBr₃, CsPbI₃, FAPbBr₃ (where FA stands for formamidinium), or a mixture thereof.

In a more specific embodiment, particles comprise a material selected from the group consisting of CdS, HgS, HgSe, HgTe, HgCdTe, PbS, PbSe, PbTe, PbCdS, PbCdSe, CuInS₂, CuInSe₂, AgInS₂, AgInSe₂, Ag₂S, Ag₂Se, InAs, InGaAs, InGaP, GaAs, or a mixture thereof.

In this disclosure, semiconductor particles may have different shapes, provided that they present a nanometric size leading to confinement of exciton created in the particle.

Semiconductor particles may have nanometric sizes in three dimensions, allowing confinement of excitons in all three spatial dimensions. Such particles are for instance nanocubes or nanospheres also known as quantum dots 1 as shown in FIG. 1.

Semiconductor particles may have a nanometric sizes in two dimensions, the third dimension being larger: excitons are confined in two spatial dimensions. Such particles are for instance nanorods, nanowires or nanorings. In this case, particles have a 2D shape.

Semiconductor particles may have a nanometric size in one dimension, the other dimensions being larger: excitons are confined in one spatial dimension only. Such particles are for instance nanoplates (or nanoplatelets) 2 as shown in FIG. 1, nanosheets, nanoribbons or nanodisks. In this case, particles have a 3D shape.

The exact shape of semiconductor particles defines confinement properties; then electronic and optical properties depending on composition of semiconductor particles, in particular the band gap. It has been also observed that particles with a nanometric size in one dimension, especially nanoplates, present a sharper decreasing zone as compared to particles with other shapes. Indeed, width of decreasing zone is enlarged if nanometric size of particles fluctuates around a mean value. When nanometric size is controlled in only one dimension, i.e. for nanoplates, by a strict number of atomic layers, thickness fluctuations are almost null and transition between absorbing and non-absorbing state is very sharp.

In one embodiment, particles have an average size ranging from 2 nm to 100 nm, preferably from 2 nm to 50 nm, more preferably from 2 nm to 20 nm, even more preferably from 2 nm to 10 nm.

In one embodiment, the largest dimension of particles ranges from 2 nm to 100 nm, preferably from 2 nm to 50 nm, more preferably from 2 nm to 20 nm, even more preferably from 2 nm to 10 nm.

In one embodiment, the smallest dimension of particles ranges from 2 nm to 100 nm, preferably from 2 nm to 50 nm, more preferably from 2 nm to 20 nm, even more preferably from 2 nm to 10 nm.

In one embodiment, the smallest dimension of particles is smaller than the largest dimension of said particle by a factor (aspect ratio) of at least about 1.5, at least about 2, at least about 2.5, at least about 3, at least about 3.5, at least about 4, at least about 4.5, or at least about 5.

In an embodiment, semiconductor particles are homostructures. By homostructure, it is meant that each particle is homogenous and has the same local composition in all its volume. In other words, each particle is a core particle without a shell.

In an alternative embodiment, semiconductor particles are heterostructures. By heterostructure, it is meant that each particle is comprised of several sub-volumes, each sub-volume having a different composition from neighbouring sub-volumes. In a particular embodiment, all sub-volumes have a composition defined by formula (I) disclosed above, with different parameters, i.e. elemental composition and stoichiometry.

Example of heterostructure are core/shell particles as shown on FIG. 1, the core having any shape disclosed above: nanosphere 11 or 44, nanoplate 33. A shell is a layer covering totally or partially the core: nanosphere 12, nanoplate 34 or 45. A particular example of core/shell heterostructure is a multi-layered structure comprising a core and several successive shells: nanospheres 12 and 13, nanoplates 34 and 35. For convenience, these multi-layered heterostructures are named core/shell hereafter. Core and shell may have the same shape—sphere 11 in sphere 12 for example—or not—dot 44 in plate 45 for instance.

In one embodiment, the quantum dots are core/shell quantum dots, the core comprising a different material from the shell.

Another example of heterostructure are core/crown particles as shown on FIG. 1, the core having any shape disclosed above. A crown 23 is a band of material disposed on the periphery of the core 22—here a nanoplate. This heterostructure is particularly useful with cores being nanoplates and crown disposed on the edges of the nanoplate.

FIG. 1 shows clear boundaries between core on one hand and shell or crown on the other hand. Heterostructures also enclose structures in which composition varies continuously from core to shell/crown: there is no precise boundary between core and shell/crown but properties in centre of the core are different from properties on the outer boundary of shell/crown.

Herein, embodiments concerning shells apply mutatis mutandis to crowns in terms of composition, thickness, properties, number of layers of material.

In one embodiment, each particle comprises a colloidal core.

In a preferred embodiment, each particle comprises a core comprising a material selected from the group comprising or consisting of CdS, PbS, PbSe, PbCdS, PbCdSe, PbTe, HgS, HgSe, HgTe, InAs, InGaAs, InGaP, GaAs, Ag₂S, Ag₂Se, CuInS₂, CuInSe₂ and mixtures thereof.

In a preferred embodiment where each particle comprises a PbS core, said PbS core has an average size ranging from 1 nm to 20 nm, preferably from 1 nm to 10 nm, more preferably from 2 nm to 8 nm.

In a preferred embodiment where each particle comprises a HgTe core, said HgTe core particle has an average size ranging from 1 nm to 50 nm, preferably from 1 nm to 10 nm.

In one embodiment, the core of the particle has a size ranging from 1 nm to 50 nm, preferably from 1 nm to 10 nm

In one embodiment, the shell has a thickness ranging from 0.1 nm to 50 nm, preferably from 0.1 nm to 20 nm, more preferably from 0.1 nm to 10 nm, even more preferably from 0.1 nm to 5 nm, most preferably from 0.1 nm to 0.5 nm.

In one embodiment, the shell is amorphous, crystalline or polycrystalline.

In one embodiment, the shell comprises or consists of 1 layer of material, 2 layers of material, 3 layers of material, 4 layers of material, 5 layers of material, 6 layers of material, 7 layers of material, 8 layers of material, 9 layers of material, 10 layers of material, 11 layers of material, 12 layers of material, 13 layers of material, 14 layers of material, 15 layers of material, 16 layers of material, 17 layers of material, 18 layers of material, 19 layers of material, 20 layers of material or more.

In an embodiment where the core is partially or totally covered or coated with two shells (or more), said shells can have distinct or same thicknesses. In other words, said shells can independently comprise distinct numbers of layers of material defined by formula (I).

In an embodiment where the core is partially or totally covered or coated with two shells (or more), said shells can comprise different or same materials defined by formula (I). For example, when the core is covered with 3 shells, the first shell (i.e. closest to the core) and the third shell can have the same composition (i.e. comprise the same material defined by formula (I)), whereas the second shell has a different composition (i.e. comprises a different material defined by formula (I)). Alternatively, the core and the second shell can have the same composition (i.e. comprise the same material defined by formula (I)), whereas the first shell and/or third shell have a different composition (i.e. comprise different materials defined by formula (I)).

In one embodiment, the core of the core/shell particle can be covered or coated with at least one shell comprising or consisting of at least one layer of an organic material.

In one embodiment, the core and the at least one shell of the core/shell particle can present a demarcated interface, i.e., the material of the core and the material of the at least one shell do not mix together.

In one embodiment, the core and the at least one shell of the core/shell particle can present a gradient interface, i.e., the material of the core and the material of the at least one shell diffusely scatter and form a fuzzy zone comprising a mixture of both the material of the core and the material of the at least one shell.

Examples of particles include, but are not limited to:
homostructures such as PbS, InAs, Ag₂S, Ag₂Se, HgTe, HgCdTe, CdS, PbSe, PbCdS, PbCdSe, PbTe, HgS, HgSe, InGaAs, InGaP, GaAs, CuInS₂, CuInSe₂,
core/shell heterostructures such as InAs/ZnS, InAs/ZnSe, InAs/CdS, InAs/CdSe, PbS/CdS, PbS/CdSe, PbSe/CdS, PbSe/CdSe, PbSe/PbS, HgS/CdS, HgS/CdSe, HgSe/CdS, HgSe/CdSe, HgSe/CdTe, HgSe/HgS, HgTe/CdS, HgTe/CdSe, HgTe/CdTe, HgTe/HgS, HgTe/HgSe, CdSe/CdS, CdSe/CdₓZn₁₋ₓS,
core/shell/shell heterostructures such as CdSe/CdS/ZnS, CdSe/ZnS/CdS, CdSe/ZnS, CdSe/CdₓZn₁₋ₓS/ZnS, CdSe/ZnS/CdₓZn₁₋ₓS, CdSe/CdS/CdₓZn₁₋ₓS, CdSe/ZnSe/ZnS, CdSe/ZnSe/CdₓZn₁₋ₓS, CdSeₓS₁₋ₓ/CdS, CdSeₓS₁₋ₓ/CdZnS, CdSeₓS₁₋ₓ/CdS/ZnS, CdSeₓS₁₋ₓ/ZnS/CdS, CdSeₓS₁₋ₓ/ZnS, CdSeₓS₁₋ₓ/CdₓZn₁₋ₓS/ZnS, CdSeₓS₁₋ₓ/ZnS/CdₓZn₁₋ₓS, CdSeₓS₁₋ₓ/CdS/CdₓZn₁₋ₓS, CdSeₓS₁₋ₓ/ZnSe/ZnS, CdSeₓS₁₋ₓ/ZnSe/CdₓZn₁₋ₓS, InP/CdS, InP/CdS/ZnSe/ZnS, InP/CdₓZn₁₋ₓS, InP/CdS/ZnS, InP/ZnS/CdS, InP/ZnS, InP/CdₓZn₁₋ₓS/ZnS, InP/ZnS/CdₓZn₁₋ₓS, InP/CdS/CdₓZn₁₋ₓS, InP/ZnSe, InP/ZnSe/ZnS, InP/ZnSe/CdₓZn₁₋ₓS, InP/ZnSeₓS₁₋ₓ, InP/GaP/ZnS, InₓZn₁₋ₓP/ZnS, InₓZn₁₋ₓP/ZnS, InP/GaP/ZnSe, InP/ZnS/ZnSe, InP/GaP/ZnSe/ZnS, and InP/ZnS/ZnSe/ZnS, PbS/CdS/ZnO, PbS/CdS/PbO, PbS/CdS/Al₂O₃, PbS/CdS/MgO, PbS/CdS/ZnS, PbS/CdS/ZnSe, PbS/CdS/ZnTe, PbS/CdSe/ZnO, PbS/CdSe/PbO, PbS/CdSe/Al₂O₃, PbS/CdSe/MgO, PbS/CdSe/CdS, PbS/CdSe/ZnS, PbS/CdSe/ZnSe, PbS/CdSe/ZnTe, PbS/CdZnS/ZnO, PbS/CdZnS/PbO, PbS/CdZnS/Al₂O₃, PbS/CdZnS/MgO, PbS/CdZnS/CdS, PbS/CdZnS/ZnS, PbS/CdZnS/ZnSe, PbS/CdZnS/ZnTe, PbS/CdZnSe/ZnO, PbS/CdZnSe/PbO, PbS/CdZnSe/Al₂O₃, PbS/CdZnSe/MgO, PbS/CdZnSe/CdS, PbS/CdZnSe/ZnS, PbS/CdZnSe/ZnSe, PbS/CdZnSe/ZnTe, PbS/ZnS/ZnO, PbS/ZnS/PbO, PbS/ZnS/Al₂O₃, PbS/ZnS/MgO, PbS/ZnS/CdS, PbS/ZnS/ZnSe, PbS/ZnS/ZnTe, PbS/ZnSe/ZnO, PbS/ZnSe/PbO, PbS/ZnSe/Al₂O₃, PbS/ZnSe/MgO, PbS/ZnSe/CdS, PbS/ZnSe/ZnS, PbS/ZnSe/ZnTe, PbSe/CdS/ZnO, PbSe/CdS/PbO, PbSe/CdS/Al₂O₃, PbSe/CdS/MgO, PbSe/CdS/ZnS, PbSe/CdS/ZnSe, PbSe/CdS/ZnTe, PbSe/CdSe/ZnO, PbSe/CdSe/PbO, PbSe/CdSe/Al₂O₃, PbSe/CdSe/MgO, PbSe/CdSe/CdS, PbSe/CdSe/ZnS, PbSe/CdSe/ZnSe, PbSe/CdSe/ZnTe, PbSe/PbS/ZnO, PbSe/PbS/PbO, PbSe/PbS/Al₂O₃, PbSe/PbS/MgO, PbSe/PbS/CdS, PbSe/PbS/ZnS, PbSe/PbS/ZnSe, PbSe/PbS/ZnTe, PbSe/CdZnS/ZnO, PbSe/CdZnS/PbO, PbSe/CdZnS/Al₂O₃, PbSe/CdZnS/MgO, PbSe/CdZnS/CdS, PbSe/CdZnS/ZnS, PbSe/CdZnS/ZnSe, PbSe/CdZnS/ZnTe, PbSe/CdZnSe/ZnO, PbSe/CdZnSe/PbO, PbSe/CdZnSe/Al₂O₃, PbSe/CdZnSe/MgO, PbSe/CdZnSe/CdS, PbSe/CdZnSe/ZnS, PbSe/CdZnSe/ZnSe, PbSe/CdZnSe/ZnTe, PbSe/ZnS/ZnO, PbSe/ZnS/PbO, PbSe/ZnS/Al₂O₃, PbSe/ZnS/MgO, PbSe/ZnS/CdS, PbSe/ZnS/ZnSe, PbSe/ZnS/ZnTe, PbSe/ZnSe/ZnO, PbSe/ZnSe/PbO, PbSe/ZnSe/Al₂O₃, PbSe/ZnSe/MgO, PbSe/ZnSe/CdS, PbSe/ZnSe/ZnS, PbSe/ZnSe/ZnTe, PbTe/CdS/ZnO, PbTe/CdS/PbO, PbTe/CdS/Al₂O₃, PbTe/CdS/MgO, PbTe/CdS/ZnS, PbTe/CdS/ZnSe, PbTe/CdS/ZnTe, PbTe/CdSe/ZnO, PbTe/CdSe/PbO, PbTe/CdSe/Al₂O₃, PbTe/CdSe/MgO, PbTe/CdSe/CdS, PbTe/CdSe/ZnS, PbTe/CdSe/ZnSe, PbTe/CdSe/ZnTe, PbTe/PbS/ZnO, PbTe/PbS/PbO, PbTe/PbS/Al₂O₃, PbTe/PbS/MgO, PbTe/PbS/CdS, PbTe/PbS/ZnS, PbTe/PbS/ZnSe, PbTe/PbS/ZnTe, PbTe/CdZnS/ZnO, PbTe/CdZnS/PbO, PbTe/CdZnS/Al₂O₃, PbTe/CdZnS/MgO, PbTe/CdZnS/CdS, PbTe/CdZnS/ZnS, PbTe/CdZnS/ZnSe, PbTe/CdZnS/ZnTe, PbTe/CdZnSe/ZnO, PbTe/CdZnSe/PbO, PbTe/CdZnSe/Al₂O₃, PbTe/CdZnSe/MgO, PbTe/CdZnSe/CdS, PbTe/CdZnSe/ZnS, PbTe/CdZnSe/ZnSe, PbTe/CdZnSe/ZnTe, PbTe/ZnS/ZnO, PbTe/ZnS/PbO, PbTe/ZnS/Al₂O₃, PbTe/ZnS/MgO, PbTe/ZnS/CdS, PbTe/ZnS/ZnSe, PbTe/ZnS/ZnTe, PbTe/ZnSe/ZnO, PbTe/ZnSe/PbO, PbTe/ZnSe/Al₂O₃, PbTe/ZnSe/MgO, PbTe/ZnSe/CdS, PbTe/ZnSe/ZnS, PbTe/ZnSe/ZnTe, CdS/PbS/ZnO, CdS/PbS/PbO, CdS/PbS/Al₂O₃, CdS/PbS/MgO, CdS/PbS/CdS, CdS/PbS/ZnS, CdS/PbS/ZnSe, CdS/PbS/ZnTe, CdS/CdSe/ZnO, CdS/CdSe/PbO, CdS/CdSe/Al₂O₃, CdS/CdSe/MgO, CdS/CdSe/CdS, CdS/CdSe/ZnS, CdS/CdSe/ZnSe, CdS/CdSe/ZnTe, CdS/CdZnS/ZnO, CdS/CdZnS/PbO, CdS/CdZnS/Al₂O₃, CdS/CdZnS/MgO, CdS/CdZnS/CdS, CdS/CdZnS/ZnS, CdS/CdZnS/ZnSe, CdS/CdZnS/ZnTe, CdS/CdZnSe/ZnO, CdS/CdZnSe/PbO, CdS/CdZnSe/Al₂O₃, CdS/CdZnSe/MgO, CdS/CdZnSe/CdS, CdS/CdZnSe/ZnS, CdS/CdZnSe/ZnSe, CdS/CdZnSe/ZnTe, CdS/ZnS/ZnO, CdS/ZnS/PbO, CdS/ZnS/Al₂O₃, CdS/ZnS/MgO, CdS/ZnS/CdS, CdS/ZnS/ZnSe, CdS/ZnS/ZnTe, CdS/ZnSe/ZnO, CdS/ZnSe/PbO, CdS/ZnSe/Al₂O₃, CdS/ZnSe/MgO, CdS/ZnSe/CdS, CdS/ZnSe/ZnS, CdS/ZnSe/ZnTe, HgTe/CdS/ZnO, HgTe/CdS/PbO, HgTe/CdS/Al₂O₃, HgTe/CdS/MgO, HgTe/CdS/ZnS, HgTe/CdS/ZnSe, HgTe/CdS/ZnTe, HgTe/CdSe/ZnO, HgTe/CdSe/PbO, HgTe/CdSe/Al₂O₃, HgTe/CdSe/MgO, HgTe/CdSe/CdS, HgTe/CdSe/ZnS, HgTe/CdSe/ZnSe, HgTe/CdSe/ZnTe, HgTe/PbS/ZnO, HgTe/PbS/PbO, HgTe/PbS/Al₂O₃, HgTe/PbS/MgO, HgTe/PbS/CdS, HgTe/PbS/ZnS, HgTe/PbS/ZnSe, HgTe/PbS/ZnTe, HgTe/CdZnS/ZnO, HgTe/CdZnS/PbO, HgTe/CdZnS/Al₂O₃, HgTe/CdZnS/MgO, HgTe/CdZnS/CdS, HgTe/CdZnS/ZnS, HgTe/CdZnS/ZnSe, HgTe/CdZnS/ZnTe, HgTe/CdZnSe/ZnO, HgTe/CdZnSe/PbO, HgTe/CdZnSe/Al₂O₃, HgTe/CdZnSe/MgO, HgTe/CdZnSe/CdS, HgTe/CdZnSe/ZnS, HgTe/CdZnSe/ZnSe, HgTe/CdZnSe/ZnTe, HgTe/ZnS/ZnO, HgTe/ZnS/PbO, HgTe/ZnS/Al₂O₃, HgTe/ZnS/MgO, HgTe/ZnS/CdS, HgTe/ZnS/ZnSe, HgTe/ZnS/ZnTe, HgTe/ZnSe/ZnO, HgTe/ZnSe/PbO, HgTe/ZnSe/Al₂O₃, HgTe/ZnSe/MgO, HgTe/ZnSe/CdS, HgTe/ZnSe/ZnS, HgTe/ZnSe/ZnTe, HgS/CdS/ZnO, HgS/CdS/PbO, HgS/CdS/Al₂O₃, HgS/CdS/MgO, HgS/CdS/ZnS, HgS/CdS/ZnSe, HgS/CdS/ZnTe, HgS/CdSe/ZnO, HgS/CdSe/PbO, HgS/CdSe/Al₂O₃, HgS/CdSe/MgO, HgS/CdSe/CdS, HgS/CdSe/ZnS, HgS/CdSe/ZnSe, HgS/CdSe/ZnTe, HgS/PbS/ZnO, HgS/PbS/PbO, HgS/PbS/Al₂O₃, HgS/PbS/MgO, HgS/PbS/CdS, HgS/PbS/ZnS, HgS/PbS/ZnSe, HgS/PbS/ZnTe, HgS/CdZnS/ZnO, HgS/CdZnS/PbO, HgS/CdZnS/Al₂O₃, HgS/CdZnS/MgO, HgS/CdZnS/CdS, HgS/CdZnS/ZnS, HgS/CdZnS/ZnSe, HgS/CdZnS/ZnTe, HgS/CdZnSe/ZnO, HgS/CdZnSe/PbO, HgS/CdZnSe/Al₂O₃, HgS/CdZnSe/MgO, HgS/CdZnSe/CdS, HgS/CdZnSe/ZnS, HgS/CdZnSe/ZnSe, HgS/CdZnSe/ZnTe, HgS/ZnS/ZnO, HgS/ZnS/PbO, HgS/ZnS/Al₂O₃, HgS/ZnS/MgO, HgS/ZnS/CdS, HgS/ZnS/ZnSe, HgS/ZnS/ZnTe, HgS/ZnSe/ZnO, HgS/ZnSe/PbO, HgS/ZnSe/Al₂O₃, HgS/ZnSe/MgO, HgS/ZnSe/CdS, HgS/ZnSe/ZnS, HgS/ZnSe/ZnS, HgS/ZnSe/ZnTe, HgSe/CdS/ZnO, HgSe/CdS/PbO, HgSe/CdS/Al₂O₃, HgS e/CdS/MgO, HgSe/CdS/ZnS, HgSe/CdS/ZnSe, HgSe/CdS/ZnTe, HgSe/CdSe/ZnO, HgSe/CdSe/PbO, HgSe/CdSe/Al₂O₃, HgSe/CdSe/MgO, HgSe/CdSe/CdS, HgSe/CdSe/ZnS, HgSe/CdSe/ZnSe, HgSe/CdSe/ZnTe, HgSe/PbS/ZnO, HgSe/PbS/PbO, HgSe/PbS/Al₂O₃, HgSe/PbS/MgO, HgSe/PbS/CdS, HgSe/PbS/ZnS, HgSe/PbS/ZnSe, HgSe/PbS/ZnTe, HgSe/CdZnS/ZnO, HgSe/CdZnS/PbO, HgSe/CdZnS/Al₂O₃, HgSe/CdZnS/MgO, HgSe/CdZnS/CdS, HgSe/CdZnS/ZnS, HgSe/CdZnS/ZnSe, HgSe/CdZnS/ZnTe, HgSe/CdZnSe/ZnO, HgSe/CdZnSe/PbO, HgSe/CdZnSe/Al₂O₃, HgSe/CdZnSe/MgO, HgSe/CdZnSe/CdS, HgSe/CdZnSe/ZnS, HgSe/CdZnSe/ZnSe, HgSe/CdZnSe/ZnTe, HgSe/ZnS/ZnO, HgSe/ZnS/PbO, HgSe/ZnS/Al₂O₃, HgSe/ZnS/MgO, HgS e/ZnS/CdS, HgSe/ZnS/ZnSe, HgSe/ZnS/ZnTe, HgSe/ZnSe/ZnO, HgSe/ZnSe/PbO, HgSe/ZnSe/Al₂O₃, HgSe/ZnSe/MgO, HgSe/ZnSe/CdS, HgSe/ZnSe/ZnS and HgSe/ZnSe/ZnTe;
   [with X/Y/Z, X being the core, Y being the first shell and Z being the second shell]; wherein x is a decimal number from 0 to 1.

In a preferred embodiment, the at least one shell of the core/shell particle comprises or consists of a material selected from the group comprising or consisting of PbS, CdS, CdSe, CdTe, CdO, CdZnS, CdZnSe, PbSe, PbTe, PbCdS, ZnS, ZnSe, HgS, HgSe, GaN, GaAs, InGaAs, InAs, InP, InGaP, CuS, CuSe, SnO₂ and mixtures thereof.

In a preferred embodiment, the particle is a core/shell particle comprising a core and a shell, wherein the particle comprises:
(i) a core comprising at least one first material selected from the group comprising or consisting of PbS, PbSe, PbTe, CdS, PbCdS, PbCdSe, HgTe, HgS, HgSe, InAs, InGaAs, InGaP, GaAs, Ag₂S, Ag₂Se, CuInS₂, CuInSe₂ and mixtures thereof and
(ii) a first shell comprising at least one second material selected from the group comprising or consisting of HgS, HgSe, CdS, PbS, CdTe, CdSe, CdZnS, CdZnSe, ZnS and ZnSe and mixtures thereof.

In a preferred embodiment, the particle is a core/shell particle comprising a core and two shells, wherein the particle comprises:
(i) a core comprising a first material selected from the group comprising or consisting of PbS, PbSe, PbCdS, PbCdSe, PbTe, HgS, HgSe, HgTe, InAs, InGaAs, InGaP, GaAs, CuInS₂, CuInSe₂ and mixtures thereof, and preferably selected from the group of PbS, PbSe, PbTe, HgTe, HgS, HgSe and mixtures thereof
(ii) a first shell comprising a second material selected from the group comprising or consisting of CdS, CdSe, CdO, CdZnS, CdZnSe, PbSe, PbTe, PbCdS, ZnS, ZnSe, HgS, GaN, GaAs, InGaAs, InAs, InP, InGaP, CuS, CuSe, SnO₂ and mixtures thereof and preferably selected from the group of CdS, CdSe, CdZnS, CdZnSe, ZnS and ZnSe, and
(iii) a second shell comprising a third material of formula MₓE_{y}, wherein:
   M is selected from the group comprising or consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs and a mixture thereof;
   E is selected from the group comprising or consisting of O, S, Se, Te, P, N and As;
   x is a decimal number with 0.05≤x≤0.95;
   y is a decimal number with 0.05≤y≤0.95; and
   x+y=1.

In a preferred embodiment, the particle is a core/shell particle comprising a core and two shells, wherein the particle comprises:
(i) a core comprising at least one first material selected from the group comprising or consisting of PbS, PbSe, PbTe, HgTe, HgS, HgSe, InAs and mixtures thereof;
(ii) a first shell comprising at least one second material selected from the group comprising or consisting of HgS, HgSe, CdS, PbS, CdTe, CdSe, CdZnS, CdZnSe, ZnS and ZnSe and mixtures thereof; and
(iii) a second shell comprising at least a third material selected from the group comprising or consisting of ZnO, PbO, Al₂O₃, MgO, CdS, ZnS, ZnSe, ZnTe and mixtures thereof.

In one embodiment, the ink of the invention comprises at least one ligand. In other words, the colloidal dispersion of particles comprises at least one ligand.

In one embodiment, the at least one ligand is selected from the group comprising or consisting of organic ligands, inorganic ligands, hybrid organic/inorganic ligands and mixtures thereof.

Inorganic ligands and hybrid organic/inorganic ligands are composed of pair of anion and cation or of a metal salt or complex, or a mixture thereof.

Suitable examples of anions include, but are not limited to, S²⁻, HS⁻, Se²⁻, HSe⁻, Te²⁻, OH⁻, BF₄⁻, PF₆⁻, Cl⁻, Br⁻, I⁻, F⁻, PbI₃⁻, PbI₄²⁻, PbI₆³⁻, CH₃COO⁻, HCOO⁻, and mixtures thereof.

Suitable examples of cations include, but are not limited to, NH₄⁺, CH₃NH₃⁺, (CH₃)₂NH₂⁺, (CH₃)₃NH⁺, (CH₃)₄N⁺, (CₓH_{y})_{z}N^{4-z+}, PbI⁺, Pb²⁺, Cs⁺, Na⁺, K⁺, Li⁺, H⁺, Bi³⁺, Sn²⁺, and mixtures thereof.

Suitable examples of metal salts and complexes include, but are not limited to, As₂S₃, As₂Se₃, Sb₂S₃, As₂Te₃, Sb₂S₃, Sb₂Se₃, Sb₂Te₃, PbC₁₂, PbI₂, PbBr₂, CdCl₂, CdBr₂, CdI₂, InCl₃, InBr₃, InI₃, and mixtures thereof.

In one embodiment, the at least one ligand is an organic or hybrid organic/inorganic ligand.

In one embodiment, the at least one ligand is a neutral molecule.

Suitable examples of neutral molecules include, but are not limited to: 2-mercaptoacetic acid, 3-mercaptopropionic acid, 12-mercaptododecanoic acid, 2-mercaptoehtyltrimethoxysilane, 3-mercaptopropyltrimethoxysilane, 12-mercaptododecyltrimethoxysilane, 11-mercapto-1-undecanol, 16-hydroxyhexadecanoic acid, ricinoleic acid, cysteamine, and a mixture thereof.

Further suitable examples of neutral molecules include, but are not limited to, C₃ to C₂₀ alkanethiols, linear or branched, such as, without limitation, propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, and a mixture thereof.

Further suitable examples of neutral molecules include, but are not limited to, thioglycerol, glycerol, 3-mercaptopropane-1,2-diol, and a mixture thereof.

Further suitable examples of neutral molecules include, but are not limited to, C₃ to C₂₀ primary amines, linear or branched, such as, without limitation, ethylamine, propylamine, isopropylamine, butylamine, isobutylamine, octylamine, pentylamine, isoamylamine, hexylamine, ethylhexylamine, aniline, oleylamine and the like, oleate and a mixture thereof.

Further suitable examples of neutral molecules include, but are not limited to, C₃ to C₂₀ secondary amines such as, without limitation, diethylamine.

Further suitable examples of neutral molecules include, but are not limited to, C₂ to C₈ tertiary amines such as, without limitation, triethylamine.

Further suitable examples of neutral molecules include, but are not limited to, phosphorus-containing molecules, such as, without limitation, phosphines, phosphonic acids, phosphinic acids, tris(hydroxymethyl)phosphine and a mixture thereof.

In one embodiment, the at least one ligand allows n-doping of the particles. In one embodiment, the at least one ligand allows p-doping of the particles.

Doping of a particle refers to the addition of very small amounts of “impurities” in order to modify the conductivity features of said particle. “n-doping” consists in producing an excess of negatively charged electrons; while “p-doping” consists in producing a deficiency in negatively charged electrons, i.e., an excess of holes (which can be considered as positively charged).

In one embodiment, n-doping ligands include, but are not limited to, lead and/or halide-containing ligands. Examples of suitable n-doping ligands include, but are not limited to, NH₄I, NH₄Br, PbI₂, PbBr₂, PbCl₂, CSI, HC(NH₂)₂PbI₃, CH₃NH₃PbI₃, CsPbI₃, RxNH₄₋ₓI [where R is a CₓH_{y} group], RₓNH₄₋ₓBr [where R is a CₓH_{y} group], RₓNH₄₋ₓCl [where R is a CₓH_{y} group], ammonium thiocyanate, 2-(2-methoxyphenyl)-1,3-dimethyl-1H-benzoimidazol-3-ium iodide and mixtures thereof.

In one embodiment, p-doping ligands include, but are not limited to, ethanedithiol, thioglycerol, 1,2-benzenedithiol, 1,4-benzenedithiol, 1,3-benzenedithiol, butanethiol, benzene thiol, 2-mercaptoacetic acid, 3-mercaptopropionic acid, ethanediamine and mixtures thereof.

In one embodiment, the ink of the invention comprises at least one liquid vehicle. In other words, the colloidal dispersion of particles comprises at least one solvent.

In one embodiment, the at least one liquid vehicle comprises or consists of at least one solvent.

In one embodiment, the at least one solvent is selected from the group comprising or consisting of pentane, hexane, heptane, cyclohexane, petroleum ether, toluene, benzene, xylene, chlorobenzene, carbon tetrachloride, chloroform, dichloromethane, 1,2-dichloroethane, THF (tetrahydrofuran), acetonitrile, acetone, ethanol, methanol, ethyl acetate, ethylene glycol, diglyme (diethylene glycol dimethyl ether), diethyl ether, DME (1,2-dimethoxy-ethane, glyme), DMF (dimethylformamide), NMF (N-methylformamide), FA (Formamide), DMSO (dimethyl sulfoxide), 1,4-dioxane, triethyl amine, and mixtures thereof.

In one embodiment, the at least one solvent is selected from the group comprising or consisting of water, hexane, heptane, pentane, octane, decane, dodecane, toluene, tetrahydrofuran, chloroform, acetone, acetic acid, n-methylformamide, n,n-dimethylformamide, dimethylsulfoxide, N-Methyl-2-pyrrolidone, propylene carbonate, octadecene, squalene, amines such as for example tri-n-octylamine, 1,3-diaminopropane, oleylamine, hexadecylamine, octadecylamine, squalene, alcohols such as for example ethanol, methanol, isopropanol, 1-butanol, 1-hexanol, 1-decanol, propane-2-ol, ethanediol, 1,2-propanediol and mixtures thereof.

In one embodiment, the at least one solvent is a polar solvent. In other words, the colloidal dispersion of particles comprises a polar solvent.

In one embodiment, the colloidal dispersion of particles comprises at least one polar solvent selected from the group comprising acetonitrile, formamide, dimethylformamide, N-methylformamide, 1,2-dichlorobenzene, 1,2-dichloroethane, 1,4-dichlorobenzene, propylene carbonate and N-methyl-2-pyrrolidone, dimethyl sulfoxide, 2,6 difluoropyridine, N,N dimethylacetamide, γ-butyrolactone, dimethylpropyleneurea, triethylphosphate, trimethylphosphate, dimethylethyleneurea, tetramethylurea, diethylformamide, o-Chloroaniline, dibutylsulfoxide, diethylacetamide, or a mixture thereof.

In one embodiment, the at least one liquid vehicle further comprises additives. In one embodiment, the additives represent from about 0.1% to about 1% of the total mass of the ink.

In one embodiment, the at least one liquid vehicle further comprises an additive for colloidal stability.

In one embodiment, the additive for colloidal stability is a metal acetate, such as for example sodium acetate.

In one embodiment, the additive for colloidal stability is selected from propylamine, butylamine, amylamine, hexylamine, aniline, triethylamine, diethylamine, isobutylamine, isopropylamine, isoamylamine, or a mixture thereof.

In one embodiment, the additive for colloidal stability is a polymer.

In one embodiment, the additive for colloidal stability is a polymer selected from the group comprising or consisting of polystyrene, poly(N-isopropyl acrylamide), polyethylene glycol, polyethylene, polybutadiene, polyisoprene, polyethylene oxide, polyethyleneimine, polymethylmethacrylate, polyethylacrylate, polyvinylpyrrolidone, polyvinylpyrollidinone, poly(4-vinylpyridine), polypropylene glycol, polydimethylsiloxane, polyisobutylene, polyaniline, polyvinylalcohol, polyvinylidene fluoride, or a blend/multiblocks polymer thereof.

In one embodiment, the ink of the invention comprises at least one metal-containing precursor.

In a specific embodiment, the metal-containing precursor is a metal halide binder selected from the group of ZnX₂, PbX₂, CdX₂, SnX₂, HgX₂, BiX₃, CsPbX₃, CsX, NaX, KX, LiX, HC(NH₂)₂PbX₃, CH₃NH₃PbX₃, or a mixture thereof, wherein X is selected from Cl, Br, I, F or a mixture thereof.

In other words, the ink comprises at least one metal halide binder.

In a preferred embodiment, the metal halide binder is a metal iodide.

The at least one metal-containing precursor may be selected from the organometallic precursors and metalloorganic precursors.

The at least one metal-containing precursor may be a compound of formula Mₓ-L_{y};
with M is metal chosen from Zn, Al, Ti, Si, Cd, and mixture thereof,
L is an organic ligand chosen from acetate, nitrate, methyl, ethyl, propyl, tertbutyl, secbutyl, N,N-dimethylaminoethoxide, dicyclohexyl, alcoxide, isopropoxide, terbutoxide, secbutoxide, halogenides such as chloride or bromide or iodide, n-butoxide, ethoxide, tetrakis(diethylamide), tetrakis(ethylmethylamide), tetrakis(dimethylamide), isopropylamino, diethyldithiocarbamate, octyl, or bis(trimethylsilyl)amide,
   wherein x and y are independently a decimal number from 1 to 5.

The at least one metal containing precursor may be selected from the group comprising or consisting of zinc acetate, zinc nitrate, ZnEt₂, Zinc N,N-dimethylaminoethoxide, dicyclohexylzinc, aluminium alkoxide, aluminium isopropoxide, aluminum terbutoxide, aluminium sec butoxide, (CH₃)₃Al, (CH₃CH₂)₃Al, AlCl₃, TiCl₄, titanium n-butoxide, titanium ethoxide, titanium isopropoxide, titanium tetrakis(diethylamide), TiI₄, tetraethyl orthosilicate, tetramethyl orthosilicate, SiCl₄, tri(isopropylamino)silane, cadmium acetate, cadmium diethyl dithiocarbamate, dimethyl cadmium, zinc diethyldithiocarbamate, and mixtures thereof.

In one embodiment, the ink of the invention is stable. In one embodiment, the colloidal dispersion of particles in the ink is stable. This means that the ink (or the colloidal dispersion of particles) is able to:
avoid flocculation (i.e. is colloidally stable);
show an unchanged absorption spectrum (i.e. same excitonic peak in terms of FWHM and wavelength, meaning that the ink is chemically stable); and/or
keep the same performances (optical and electrical) at ambient temperature (20° C.-60° C.) upon deposition on a substrate after storage for a given period of time.

In one embodiment, the colloidal dispersion of particles or the ink is stable over environmental conditions. Examples of such environmental conditions include, but are not limited to, water exposure, humidity, air exposure, oxygen exposure, time, temperature, irradiance, voltage and the like.

In one embodiment, the colloidal dispersion of particles or the ink is stable over time at ambient temperature, 5° C. and/or −20° C. In one embodiment, the colloidal dispersion of particles or the ink is stable over a time period ranging from 1 minute to 60 minutes, from 5 minutes to 30 minutes, or from 5 minutes to 15 minutes. In one embodiment, the colloidal dispersion of particles or the ink is stable over a time period ranging from 1 hour to 168 hours, from 1 hour to 100 hours, from 1 hour to 72 hours, from 1 hour to 48 hours, from 1 hour to 24 hours, from 1 hour to 12 hours. In one embodiment, the colloidal dispersion of particles or the ink is stable over a time period ranging from 1 day to 90 days, from 7 days to 60 days, from 1 day to 30 days, or from 1 day to 15 days. In one embodiment, the colloidal dispersion of particles or the ink is stable over a time period ranging from 1 week to 52 weeks, from 4 weeks to 24 weeks, or from 4 weeks to 12 weeks. In one embodiment, the colloidal dispersion of particles or the ink is stable over a time period ranging from 1 month to 60 months, from 1 month to 36 months, from 1 month to 24 months, from 6 months to 24 months, or from 6 months to 12 months.

In one embodiment, the colloidal dispersion of particles or the ink is stable over temperature, i.e., when stressed by low, medium or high temperatures. In one embodiment, the colloidal dispersion of particles or the ink is stable over a low temperature ranging from −100° C. to 5° C., from −30° C. to −5° C., from 0° C. to 14° C., from 0° C. to 10° C., or from 0° C. to 5° C. In one embodiment, the colloidal dispersion of particles or the ink is stable over a medium temperature (i.e., at room temperature) ranging from 15° C. to 30° C., from 15° C. to 25° C., from 15° C. to 20° C., or from 20° C. to 25° C.

In one embodiment, the colloidal dispersion of particles or the ink is stable over humidity, i.e., when subjected to high humidity. In one embodiment, the colloidal dispersion of particles or the ink is stable over a relative humidity percentage ranging from 0% to 100%, preferably from 10% to 90%, more preferably from 25% to 75%, even more preferably from 50% to 75%.

In one embodiment, the stability of the colloidal dispersion of particles or the ink can be assessed by measuring the absorbance of the colloidal dispersion of particles, in particular of the ink. In this embodiment, the absorbance of colloidal dispersion of particles, in particular of the ink, provides information on the precipitation of the particles in said dispersion, in particular in said ink.

Methods for measuring the absorbance of a colloidal dispersion of particles, in particular of an ink, are well known to the one skilled in the art, and include, without limitation, absorption spectroscopy, UV-visible spectrophotometry, IR spectrophotometry, analytical centrifugation, analytical ultracentrifugation, and the like.

In one embodiment, the colloidal dispersion of particles is considered as stable if the absorbance at 450 nm or 600 nm does not decrease over time, the excitonic peak wavelength does not shift, and/or the FWHM does not increase over time.

In one embodiment, the colloidal dispersion of particles is considered as stable if the absorbance at 450 nm or 600 nm of said dispersion, in particular of the ink, does not decrease by more than 50%, preferably 40%, 30%, 25%, 20%, 15%, 10%, 5%, 4%, 3%, 2%, 1%, or 0% over time.

In one embodiment, the colloidal dispersion of particles is considered as stable if the excitonic peak wavelength does not shift by more than 5 nm, 10 nm or 15 nm over time. In one embodiment, the colloidal dispersion of particles is considered as stable if the FWHM does not increase by more than 5 nm, 10 nm or 15 nm over time.

In one embodiment, the colloidal dispersion of particles is considered as stable if the absorbance at 450 nm or 600 nm of said dispersion, in particular of the ink, does not decrease by more than 50%, preferably 25%, 20%, 15%, 10%, 5%, or 0% over a time period ranging from 1 minute to 60 minutes, from 5 minutes to 30 minutes, or from 5 minutes to 15 minutes.

In one embodiment, the colloidal dispersion of particles is considered as stable if the excitonic peak wavelength does not shift by more than 5 nm, 10 nm or 15 nm over a time period ranging from 1 minute to 60 minutes, from 5 minutes to 30 minutes, or from 5 minutes to 15 minutes. In one embodiment, the colloidal dispersion of particles is considered as stable if the FWHM does not increase by more than 5 nm, 10 nm or 15 nm over a time period ranging from 1 minute to 60 minutes, from 5 minutes to 30 minutes, or from 5 minutes to 15 minutes.

In one embodiment, the colloidal dispersion of particles is considered as stable if the absorbance at 450 nm or 600 nm of said dispersion, in particular of the ink, does not decrease by more than 50%, preferably 25%, 20%, 15%, 10%, 5%, or 0% over a time period ranging from 1 hour to 168 hours, from 1 hour to 72 hours, from 1 hour to 48 hours, from 1 hour to 24 hours, or from 24 hours to 72 hours.

In one embodiment, the colloidal dispersion of particles is considered as stable if the excitonic peak wavelength does not shift by more than 5 nm, 10 nm or 15 nm over a time period ranging from 1 hour to 168 hours, from 1 hour to 72 hours, from 1 hour to 48 hours, from 1 hour to 24 hours, or from 24 hours to 72 hours. In one embodiment, the colloidal dispersion of particles is considered as stable if the FWHM does not increase by more than 5 nm, 10 nm or 15 nm over a time period ranging from 1 hour to 168 hours, from 1 hour to 72 hours, from 1 hour to 48 hours, from 1 hour to 24 hours, or from 24 hours to 72 hours.

In one embodiment, the colloidal dispersion of particles is considered as stable if the absorbance at 450 nm or 600 nm of said dispersion, in particular of the ink, does not decrease by more than 50%, preferably 25%, 20%, 15%, 10%, 5%, or 0% over a time period ranging from 1 day to 90 days, from 7 days to 60 days, from 1 day to 30 days, or from 1 day to 15 days.

In one embodiment, the colloidal dispersion of particles is considered as stable if the excitonic peak wavelength does not shift by more than 5 nm, 10 nm or 15 nm over a time period ranging from 1 day to 90 days, from 7 days to 60 days, from 1 day to 30 days, or from 1 day to 15 days. In one embodiment, the colloidal dispersion of particles is considered as stable if the FWHM does not increase by more than 5 nm, 10 nm or 15 nm over a time period ranging from 1 day to 90 days, from 7 days to 60 days, from 1 day to 30 days, or from 1 day to 15 days.

In one embodiment, the colloidal dispersion of particles is considered as stable if the absorbance of said dispersion, in particular of the ink, does not decrease by more than 50%, preferably 25%, 20%, 15%, 10%, 5%, or 0% over a time period ranging from 1 week to 52 weeks, from 4 weeks to 24 weeks, or from 4 weeks to 12 weeks.

In one embodiment, the colloidal dispersion of particles is considered as stable if the excitonic peak wavelength does not shift by more than 5 nm, 10 nm or 15 nm over a time period ranging from 1 week to 52 weeks, from 4 weeks to 24 weeks, or from 4 weeks to 12 weeks. In one embodiment, the colloidal dispersion of particles is considered as stable if the FWHM does not increase by more than 5 nm, 10 nm or 15 nm over a time period ranging from 1 week to 52 weeks, from 4 weeks to 24 weeks, or from 4 weeks to 12 weeks.

In one embodiment, the colloidal dispersion of particles is considered as stable if the absorbance of said dispersion, in particular of the ink, does not decrease by more than 50%, preferably 25%, 20%, 15%, 10%, 5%, or 0% over a time period ranging from 1 month to 60 months, from 1 month to 36 months, from 1 month to 24 months, from 6 months to 24 months, or from 6 months to 12 months.

In one embodiment, the colloidal dispersion of particles is considered as stable if the excitonic peak wavelength does not shift by more than 5 nm, 10 nm or 15 nm over a time period ranging from 1 month to 60 months, from 1 month to 36 months, from 1 month to 24 months, from 6 months to 24 months, or from 6 months to 12 months. In one embodiment, the colloidal dispersion of particles is considered as stable if the FWHM does not increase by more than 5 nm, 10 nm or 15 nm over a time period ranging from 1 month to 60 months, from 1 month to 36 months, from 1 month to 24 months, from 6 months to 24 months, or from 6 months to 12 months.

In one embodiment, the colloidal dispersion of particles is considered as stable if it meets at least one stability test requirement.

In one embodiment, the colloidal dispersion of particles is considered as stable if it meets at least one of the stability “Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and/or “Test F-4” requirements, requirement as defined hereafter.

In one embodiment, the colloidal dispersion of particles is considered as stable if it meets any two of the stability “Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and “Test F-4” requirements.

In one embodiment, the colloidal dispersion of particles is considered as stable if it meets any three of the stability “Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and “Test F-4” requirements.

In one embodiment, the colloidal dispersion of particles is considered as stable if it meets any four of the stability “Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and “Test F-4” requirements.

In one embodiment, the colloidal dispersion of particles is considered as stable if it meets any five of the stability “Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and “Test F-4” requirements.

In one embodiment, the colloidal dispersion of particles is considered as stable if it meets any six of the stability “Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and “Test F-4” requirements.

Tests A, B, C, D, E, F consist in measuring the stability of the colloidal dispersion of particles, in particular of the ink, under medium thermal stress conditions (i.e., at room temperature) for 1 month (Test A), for 2 months (Test B), for 3 months (Test C), for 6 months (Test D), for 9 months (Test E), for 12 months (Test F). It is considered that the colloidal dispersion of particles is stable if the absorbance at 450 nm or 600 nm of said dispersion, in particular of the ink, does not decrease, if the excitonic peak wavelength does not shift and/or if the FWHM does not increase in conditions wherein said dispersion, in particular the ink, is exposed to conditions summarized in Table 1.

TABLE 1
Tests conditions

| | Temperature storage | | |
|---|---|---|---|
| Test | (° C.) | Time storage | |
| Test A-1 | about 15 | 1 | month |
| Test A-2 | about 20 | 1 | month |
| Test A-3 | about 25 | 1 | month |
| Test A-4 | about 30 | 1 | month |
| Test A-5 | about 5° C. | 1 | month |
| Test A-6 | about −20° C. | 1 | month |
| Test B-1 | about 15 | 2 | months |
| Test B-2 | about 20 | 2 | months |
| Test B-3 | about 25 | 2 | months |
| Test B-4 | about 30 | 2 | months |
| Test B-5 | about 5° C. | 1 | month |
| Test B-6 | about −20° C. | 1 | month |
| Test C-1 | about 15 | 3 | months |
| Test C-2 | about 20 | 3 | months |
| Test C-3 | about 25 | 3 | months |
| Test C-4 | about 30 | 3 | months |
| Test C-5 | about 5° C. | 1 | month |
| Test C-6 | about −20° C. | 1 | month |
| Test D-1 | about 15 | 6 | months |
| Test D-2 | about 20 | 6 | months |
| Test D-3 | about 25 | 6 | months |
| Test D-4 | about 30 | 6 | months |
| Test D-5 | about 5° C. | 1 | month |
| Test D-6 | about −20° C. | 1 | month |
| Test E-1 | about 15 | 9 | months |
| Test E-2 | about 20 | 9 | months |
| Test E-3 | about 25 | 9 | months |
| Test E-4 | about 30 | 9 | months |
| Test E-5 | about 5° C. | 1 | month |
| Test E-6 | about −20° C. | 1 | month |
| Test F-1 | about 15 | 12 | months |
| Test F-2 | about 20 | 12 | months |
| Test F-3 | about 25 | 12 | months |
| Test F-4 | about 30 | 12 | months |
| Test F-5 | about 5° C. | 1 | month |
| Test F-6 | about −20° C. | 1 | month |

In one embodiment, the requirements of any test (“Test A-1”, “Test A-2”, Test A-3”, “Test A-4”, “Test B-1”, “Test B-2”, Test B-3”, “Test B-4”, “Test C-1”, “Test C-2”, Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and/or “Test F-4”) are met if the absorbance of said dispersion, in particular of said ink, measured after X month of exposure (i.e., at T_{+X}) has not decreased by more than 50%, preferably 40%, 30%, 25%, 20%, 15%, 10%, 5%, 4%, 3%, 2%, 1%, or 0%, as compared to the absorbance of said dispersion, in particular of said ink, measured before the test (i.e., at T₀), wherein X is 1 for “Tests A”, 2 for “Tests B”, 3 “for Tests C”, 6 “for Tests D”, 9 “for Tests E” and 12 for “Tests F”.

In one embodiment, the requirements of any test (“Test A-1”, “Test A-2”, Test A-3”, “Test A-4”, “Test B-1”, “Test B-2”, Test B-3”, “Test B-4”, “Test C-1”, “Test C-2”, “Test C-3”, “Test C-4”, “Test D-1”, “Test D-2”, Test D-3”, “Test D-4”, “Test E-1”, “Test E-2”, Test E-3”, “Test E-4”, “Test F-1”, “Test F-2”, Test F-3″ and/or “Test F-4”) are met if:

$$100 - ( 100 \times \frac{Abs ( {T}_{+ X} )}{Abs ( {T}_{0} )} )$$

is lower than 50, preferably lower than 40, 30, 25, 20, 15, 10, 5, 4, 3, 2, or 1; wherein:
Abs(T_{+X}) is the absorbance of a colloidal dispersion of particles, in particular of the ink, measured after X month of exposure to a room temperature of about 15° C. (Test A-1, B-1, C-1, D-1, E-1 or F-1), or of about 20° C. (Test A-2, B-2, C-2, D-2, E-2 or F-2), or of about 25° C. (Test A-3, B-3, C-3, D-3, E-3 or F-3), or of about 30° C. (Test A-4, B-4, C-4, D-4, E-4 or F-4) according to the tests described hereinabove;
X is the number of months of exposure, being 1 for “Tests A”, 2 for “Tests B”, 3 “for Tests C”, 6 “for Tests D”, 9 “for Tests E” and 12 “for Tests F”; and
Abs(T₀) is the absorbance of a colloidal dispersion of particles, in particular of the ink, measured before the test described hereinabove.

In a preferred embodiment, the ink comprises:
particles, wherein the amount of particles in the ink is ranging from 1 to 40 wt %, preferably from 1 to 25 wt %, more preferably from 1 to 20 wt %;
at least one solvent, wherein the amount of solvent in the ink is ranging from 25 to 97 wt %, preferably from 35 to 80 wt %, more preferably from 45 to 70 wt %;
at least one ligand, wherein the amount of ligand in the ink is ranging from 0.1 to 8 wt %, preferably from 1 to 5 wt %, more preferably from 1 to 3 wt %; and
at least one metal halide binder wherein the amount of metal halide binder is ranging from 1 to 60%, preferably from 10 to 40 wt %, more preferably from 15 to 30 wt %.
   wherein the amount of each component of the ink (particles, solvent, ligand, metal halide binder) is based on the total weight of the ink.

In a preferred embodiment, the ink comprises:
a) a colloidal dispersion of PbS quantum dots comprising butylamine and sodium acetate in a mixture of DMF and acetonitrile, wherein the amount of PbS quantum dots is ranging from 10 to 20 wt %, the amount of butylamine is ranging from 1 to 3 wt %, the amount of DMF/acetonitrile is ranging from 45 to 70 wt %; and
b) CsI and PbI₂ solubilized in colloidal dispersion a), wherein the amount of metal halide binder is ranging from 15 to 30 wt %.

In a preferred embodiment, the ink comprises:
a) a colloidal dispersion of PbS quantum dots comprising butylamine and sodium acetate in a mixture of DMF and acetonitrile, wherein the amount of PbS quantum dots is ranging from 10 to 20 wt %, the amount of butylamine is ranging from 1 to 3 wt %, the amount of DMF/acetonitrile is ranging from 45 to 70 wt %; and
b) NaI and PbI₂ solubilized in colloidal dispersion a), wherein the amount of metal halide binder is ranging from 15 to 30 wt %.

In a preferred embodiment, the ink comprises:
a) a colloidal dispersion of PbS quantum dots comprising butylamine and sodium acetate in a mixture of DMF and acetonitrile, wherein the amount of PbS quantum dots is ranging from 10 to 20 wt %, the amount of butylamine is ranging from 1 to 3 wt %, the amount of DMF/acetonitrile is ranging from 45 to 70 wt %; and
b) KI and PbI₂ solubilized in colloidal dispersion a), wherein the amount of metal halide binder is ranging from 15 to 30 wt %.

In this embodiment, sodium acetate promotes ligand exchange from organic ligands to PbI₂, NaI, Ki and/or CsI. Sodium acetate may be replaced by other metal acetate or metal formate, or ammonium acetate or ammonium formate, or acetic acid or formic acid.

In a preferred embodiment, the ink comprises:
a) a colloidal dispersion of InAs/ZnX (X=Se, S or a mixture thereof) quantum dots comprising butylamine in DMF, wherein the amount of InAs/ZnX quantum dots is ranging from 10 to 20 wt %, the amount of butylamine is ranging from 1 to 3 wt %, the amount of DMF is ranging from 45 to 70 wt %; and
b) ZnCl₂ solubilized in colloidal dispersion a), wherein the amount of metal halide binder is ranging from 15 to 30 wt %.

The present invention also relates to a method for preparing a light-sensitive material comprising the steps of:
a) depositing an ink of the invention onto a substrate;
b) annealing deposited ink.

Herein, a light-sensitive material may be a light-absorbing material or light-emitting material.

In one embodiment, the method for preparing a light-sensitive material comprises the steps of:
a1) providing the ink of the invention;
a2) depositing said ink onto a substrate, thereby obtaining a film;
b) annealing the film obtained in step a2).

In one embodiment, the method further comprises a step of elimination of the solvent comprised in the colloidal dispersion of particles prior the annealing step. Examples of methods to eliminate the solvent include but are not limited to: evaporation under ambient conditions, vaporization under vacuum, heating, washing with another solvent, a combination thereof, or any other means known by the person skilled in the art.

The ink is as described hereinabove.

In one embodiment, the step of depositing said ink onto a substrate is achieved by a method selected from drop-casting, spin-coating, dip-coating, inkjet printing, lithography, spray coating, plating, electroplating, electrophoretic deposition, doctor blading, a Langmuir-Blodgett method, or any other means known by the person skilled in the art.

Inkjet printing is preferably used to deposit the ink onto a substrate with great precision. Spray coating is preferably used to deposit the ink onto a large area of a substrate.

An example of method for depositing the ink of the invention onto a substrate is described in International patent application publication WO2015121827 (translated into English in US patent application publication US20170043369), which is hereby incorporated by reference in its entirety.

In one embodiment, the step of depositing said ink onto a substrate comprises the deposition of 1 layer of material or ink. In one embodiment, the step of depositing said ink onto a substrate comprises the deposition of more than 1 layer of ink, such as 2 layers, 3 layers, 4 layers, 5 layers or more.

In one embodiment, steps a) and b) are repeated several times: one layer of ink is deposited on the substrate, then annealed. Subsequently, a second layer of ink is deposited, then annealed and so on. Preferably, steps a)-b) are repeated from 2 to 5 times. In this embodiment, the different layers of inks deposited may be obtained from inks with different concentrations of constituants (i.e. particles, solvent, ligand, metal halide binder) and/or at least one different constituant (i.e. different particles, different solvent, different ligand, and/or different metal halide binder), while the subsequent annealing steps may be operated at different temperatures and/or for a different period of time.

In a preferred embodiment, the method for preparing a light-sensitive material comprises the steps of:
depositing a first ink comprising a first concentration of particles onto a substrate;
annealing said first deposited ink at a temperature ranging from 50° C. to 100° C., preferably 70° C., for a period of time ranging from 10 minutes to 30 minutes, preferably 10 minutes;
depositing a second ink comprising a second concentration of particles onto the first deposited and annealed ink; and
annealing both deposited inks at a temperature ranging from 100° C. to 200° C., preferably 150° C., for a period of time ranging from 2 hours to 4 hours, preferably 3 hours.

In one embodiment, the step of depositing said ink onto a substrate further comprises a substep of washing the deposited ink before the annealing step. In this embodiment, the washing allows to remove the excess of ions and solvent.

In one embodiment, the substep of washing the deposited ink is achieved using at least one solvent. In this embodiment, the at least one solvent is selected from the group comprising or consisting of water, pentane, hexane, heptane, octane, decane, dodecane, cyclohexane, petroleum ether, toluene, benzene, xylene, chlorobenzene, carbon tetrachloride, chloroform, dichloromethane, 1,2-dichloroethane, THF (tetrahydrofuran), acetonitrile, acetone, ethanol, methanol, ethyl acetate, ethylene glycol, acetic acid, diglyme (diethylene glycol dimethyl ether), diethyl ether, DME (1,2-dimethoxy-ethane, glyme), DMF (dimethylformamide), NMF (N-methylformamide), FA (Formamide), DMSO (dimethyl sulfoxide), N-Methyl-2-pyrrolidone, propylene carbonate, octadecene, squalene, amines such as for example tri-n-octylamine, 1,3-diaminopropane, oleylamine, 1,4-dioxane, triethyl amine, hexadecylamine, octadecylamine, alcohols such as for example ethanol, methanol, isopropanol, 1-butanol, 1-hexanol, 1-decanol, propane-2-ol, ethanediol, 1,2-propanediol or mixtures thereof.

In one embodiment, the at least one solvent for washing is identical to the solvent comprised in the ink. In one embodiment, the at least one solvent for washing is different from the solvent comprised in the ink.

In one embodiment, the deposited ink is annealed at a temperature ranging from 20° C. to 250° C., preferably from about 50° C. to about 200° C., more preferably from about 100° C. to about 150° C., even more preferably from about 120° C. to about 150° C.

In one embodiment, the deposited ink is annealed for a period of time ranging from 10 minutes to 5 hours, preferably from 10 minutes to 2 hours, more preferably from 20 minutes to 1 hour, even more preferably from 20 minutes to 45 minutes.

This annealing step is particularly advantageous as it allows for a slow evaporation of the solvent still present in the deposited ink, preventing the appearance of cracks in the material obtained after. Cracks in the obtained material or film will result in a loss of electrical conductivity along said material or film and have to be avoided. Also, the association of the metal halide binder at the surface of particles and the annealing step enable the deposited ink to withstand the thermal treatment of the device in which it can be incorporated (typically 150° C. for 3 hours) and keep good optical and electrical performances.

In one embodiment, the annealing step is performed under ambient atmosphere, inert atmosphere or vacuum.

In one embodiment, the method further comprises a step of contacting the deposited ink with at least one gas or liquid. In one embodiment, this step is performed before the annealing step. In this embodiment, the at least one gas or liquid chemically reacts with one of the constituents of the deposited ink (such as, e.g., the at least one metal halide binder) to form a thin layer of metal halide surrounding the particles. Suitable examples of gas or a liquid include, without limitation, gaseous H₂S, water vapor, and O₂.

In one embodiment, said thin layer of metal halide protects the particles from oxidization, while conducting heat and electricity.

In one embodiment, the method further comprises a step of coating the deposited ink with a capping layer, said step may be performed after the annealing step. In this embodiment, the capping layer can be deposited by PECVD (Plasma Enhanced Chemical Vapor Deposition), ALD (Atomic Layer Deposition), CVD (Chemical Vapor Deposition), iCVD (Initiator Chemical Vapor Deposition), Cat-CVD (Catalytic Chemical Vapor Deposition) chemical bath deposition.

In one embodiment, the capping layer (also called protective layer) is an oxygen and/or water impermeable or non-permeable layer (is an O₂ insulating layer or a H₂O insulating layer). In this embodiment, the capping layer is a barrier against oxidation, and limits or prevents the degradation of the chemical and physical properties of the deposited ink, annealed ink, film or material obtained by the method of the invention from molecular oxygen and/or water.

In one embodiment, the capping layer is free of oxygen and/or water.

In one embodiment, the capping layer is configured to ensure the thermal management of the particles' temperature.

In one embodiment, the capping layer is thermally conductive. In this embodiment, the capping layer has a thermal conductivity in standard conditions ranging from about 0.1 to about 450 W/(m·K), preferably from about 1 to about 200 W/(m·K), more preferably from about 10 to about 150 W/(m·K).

In one embodiment, the capping layer is an inorganic layer or a polymer layer.

In one embodiment, the capping layer can be made of glass; PET (Polyethylene terephthalate); PDMS (Polydimethylsiloxane); PES (Polyethersulfone); PEN (Polyethylene naphthalate); PC (Polycarbonate); PI (Polyimide); PNB (Polynorbornene); PAR (Polyarylate); PEEK (Polyetheretherketone); PCO (Polycyclic olefins); PVDC (Polyvinylidene chloride); PMMA, poly(lauryl methacrylate); glycolyzed poly(ethylene terephthalate); poly(maleic anhydride-altoctadecene); silicon-based polymer; PET; PVA; fluorinated polymer, such as, e.g., PVDF or a derivative of PVDF; Nylon; ITO (Indium tin oxide); FTO (Fluorine doped tin oxide); cellulose; Al₂O₃, AlOₓN_{y}, SiOₓC_{y}, SiO₂, SiOₓ, SiNₓ, SiCₓ, ZrO₂, TiO₂, MgO, ZnO, SnO₂, ZnS, ZnSe, IrO₂, As₂S₃, As₂Se₃, nitrides (including, but not limited to, TiN, Si₃N₄, MoN, VN, TaN, Zr₃N₄, HfN, FeN, NbN, GaN, CrN, AlN, InN, TiₓN_{y}, SiₓN_{y}, BₓN_{y}, MoₓN_{y}, VₓN_{y}, TaₓN_{y}, ZrₓN_{y}, HfₓN_{y}, FeₓN_{y}, NbₓN_{y}, GaₓN_{y}, CrₓN_{y}, AlₓN_{y}, InₓN_{y}, or a mixture thereof; x and y are independently a decimal number from 0 to 5, at the condition that x and y are not simultaneously equal to 0, and x 0); ceramic; organic modified ceramic; or mixture thereof.

In one embodiment, the polymer capping layer may be a polymerized solid made from alpha-olefins, dienes (such as, e.g., butadiene and chloroprene), styrene, alpha-methyl styrene and the like, heteroatom substituted alpha-olefins (such as, e.g., vinyl acetate), vinyl alkyl ethers (such as, e.g., ethyl vinyl ether, vinyltrimethylsilane, vinyl chloride), tetrafluoroethylene, chlorotrifiuoroethylene, cyclic and polycyclic olefin compounds (such as, e.g., cyclopentene, cyclohexene, cycloheptene, cyclooctene, and cyclic derivatives up to C₂₀), polycyclic derivates (such as, e.g., norbornene and similar derivatives up to C₂₀), cyclic vinyl ethers (such as, e.g., 2,3-dihydrofuran, 3,4-dihydropyran and similar derivatives), allylic alcohol derivatives (such as, e.g., vinylethylene carbonate), disubstituted olefins (such as, e.g., maleic and fumaric compounds, for example, maleic anhydride, diethylfumarate and the like), poly-p-xylylene, p-quinodimethane, and mixture thereof.

In one embodiment, the capping layer may comprise scattering particles. Examples of scattering particles include, but are not limited to, SiO₂, ZrO₂, ZnO, MgO, SnO₂, TiO₂, Ag, Au, alumina, Ag, Au, barium sulfate, PTFE, barium titanate and the like.

In one embodiment, the capping layer further comprises thermal conductor particles. Examples of thermal conductor particles include, but are not limited to, SiO₂, ZrO₂, ZnO, MgO, SnO₂, TiO₂, CaO, alumina, barium sulfate, PTFE, barium titanate and the like. In this embodiment, the thermal conductivity of the capping layer is increased.

In one embodiment, the capping layer is optically transparent. In particular, the capping layer is optically transparent at wavelengths where the particles are absorbing.

In one embodiment, the capping layer has a thickness ranging from about 1 nm to about 10 mm, preferably from about 10 nm to about 10 μm, and more preferably from about 20 nm to about 1 μm.

In one embodiment, the capping layer covers and/or surrounds partially or totally the deposited ink, light-sensitive material or light-sensitive film obtained by the method of the invention.

In one embodiment, the substrate comprises glass, CaF₂, undoped Si, undoped Ge, ZnSe, ZnS, KBr, LiF, Al₂O₃, KCl, BaF₂, CdTe, NaCl, KRS-5, ZnO, SnO, MgO, ITO (indium tin oxide), FTO (fluorine doped tin oxide), SiO₂, CsBr, MgF₂, KBr, GaN, GaAsP, GaSb, GaAs, GaP, InP, Ge, SiGe, InGaN, GaAlN, GaAlPN, AlN, AlGaAs, AlGaP, AlGaInP, AlGaN, AlGaInN, LiF, SiC, BN, Au, Ag, Pt, Ru, Ni, Co, Cr, Cu, Sn, Rh Pd, Mn, Ti, diamond, fused silica, quartz, undoped double side polished wafer, silicon wafer, and highly resistive silicon wafer, a stack thereof or a mixture thereof.

In one embodiment, the substrate is optically transparent at wavelengths ranging from 900 nm to 1000 nm, and/or from 1300 nm to 1500 nm.

In one embodiment, the substrate is reflective. In this embodiment, the substrate comprises or consists of a material allowing to reflect the light, such as, e.g., a metal like aluminium, silver, a glass, a polymer or a plastic.

In one embodiment, the substrate is thermally conductive. In this embodiment, the substrate has a thermal conductivity in standard conditions ranging from about 0.5 to about 450 W/(m·K), preferably from about 1 to about 200 W/(m·K), more preferably from about 10 to about 150 W/(m·K).

In one embodiment, the substrate is used as a mechanical support.

In one embodiment, the substrate combines mechanical and optical properties.

In one embodiment, the substrate is partly or totally optically transparent in the infrared range, in the near infrared range, in the short-wave infrared range, i.e., from about 0.8 to about 2.5 μm.

In one embodiment, the substrate has a transmission higher than about 20%, preferably higher than about 50% and more preferably higher than about 80% in the infrared range.

In one embodiment, the substrate has a transmission higher than about 20%, preferably higher than about 50% and more preferably higher than about 80% in the near infrared range.

In one embodiment, the substrate has a transmission higher than about 20%, preferably higher than about 50% and more preferably higher than about 80% in the short-wave infrared range, i.e., from about 0.8 to about 2.5 μm.

In one embodiment, the substrate is electrically insulating. In a particular embodiment, the substrate has a resistivity higher than about 100 Ω·cm, about 500 Ω·cm, about 1000 Ω·cm, about 5000 Ω·cm, or about 10000 Ω·cm.

In one embodiment, the substrate is rigid, not flexible.

In one embodiment, the substrate is flexible.

In one embodiment, the substrate is patterned.

In one aspect, the invention relates to a light-sensitive material obtainable by the method of the invention.

Herein, the light-sensitive material is a light-absorbing material or a light-emitting material.

In one embodiment, the light-sensitive material has a shape of a film.

In one embodiment, the light-sensitive material is a continuous electrically conductive film comprising particles bound by a metal halide.

In one embodiment, the light-sensitive material is a photosensitive film (also called light-sensitive film). In other words, the photosensitive film is a continuous electrically conductive film comprising particles bound by a metal halide. Herein a photosensitive film refers to a photoabsorptive film or a photoemitting film. In this embodiment, a light-absorbing material refers to a photoabsorptive film, and a light-emitting material refers to a photoemitting film.

In one embodiment, the photosensitive film has an absorption coefficient ranging from about 100 cm⁻¹ to about 5×10⁵ cm⁻¹ at the first optical feature, preferably from about 500 cm⁻¹ to about 10⁵ cm⁻¹, more preferably from about 1000 cm⁻¹ to about 10⁴ cm⁻¹.

In one embodiment, the photosensitive film has a thickness ranging from about 50 nm to about 1 μm, preferably from about 100 nm to about 1 μm, more preferably from about 100 nm to about 500 nm, even more preferably from about 300 nm to about 500 nm.

In one embodiment, the photosensitive film has an area ranging from about 100 nm² to about 1 m², preferably from about 50 μm² to about 1 cm², more preferably from 100 nm² to 50 μm².

In one embodiment, the photosensitive film is further protected by at least one capping layer. Said capping layer is as described hereinabove.

In one embodiment, the photosensitive film is stable over environmental conditions (water exposure, humidity, air exposure, oxygen exposure, temperature, time, irradiance, voltage and the like).

This means that the photosensitive film is able to:
show an unchanged absorption spectrum (i.e. same excitonic peak in terms of FWHM and wavelength, meaning that the photosensitive film is chemically stable); and/or
keep the same electrical performances at ambient temperature (20° C.-60° C.).

This may especially apply if said photosensitive film has undergone thermal treatments that may occur during the fabrication of an optoelectronic device or during the operation of said device (typically from 100° C. to 200° C. for 30 minutes to several hours), and/or after a long storage at any temperature.

In one embodiment, the photosensitive film is stable over time at ambient temperature, 5° C. and/or −20° C. In one embodiment, the photosensitive film is stable over a time period ranging from 1 minute to 60 minutes, from 5 minutes to 30 minutes, or from 5 minutes to 15 minutes. In one embodiment, the photosensitive film is stable over a time period ranging from 1 hour to 168 hours, from 1 hour to 100 hours, from 1 hour to 72 hours, from 1 hour to 48 hours, from 1 hour to 24 hours, from 1 hour to 12 hours. In one embodiment, the photosensitive film is stable over a time period ranging from 1 day to 90 days, from 7 days to 60 days, from 1 day to 30 days, or from 1 day to 15 days. In one embodiment, the photosensitive film is stable over a time period ranging from 1 week to 52 weeks, from 4 weeks to 24 weeks, or from 4 weeks to 12 weeks. In one embodiment, the photosensitive film is stable over a time period ranging from 1 month to 60 months, from 1 month to 36 months, from 1 month to 24 months, from 6 months to 24 months, or from 6 months to 12 months.

In one embodiment, the photosensitive film is stable over temperature, i.e., when stressed by high temperatures. In one embodiment, the photosensitive film is stable over a temperature ranging from −100° C. to 250° C., from −100° C. to 5° C., from −30° C. to −5° C., from 25° C. to 250° C., from 50° C. to 200° C., from 50° C. to 150° C., from 100° C. to 150° C., from 120° C. to 150° C. In a preferred embodiment, the ink is stable at about 150° C.

In one embodiment, the photosensitive film is stable over humidity, i.e., when subjected to high humidity. In one embodiment, the photosensitive film is stable over a relative humidity percentage of ranging from 0% to 100%, preferably from 10% to 90%, more preferably from 25% to 75%, even more preferably from 50% to 75%.

In one embodiment, the photosensitive film is stable over irradiance, i.e., when irradiated by light, such as for example by visible-wavelength light.

In one embodiment, the photosensitive film is stable when receiving a radiant flux ranging from 1 W/m² to 100 W/m², or from 0.1 kW/m² to 100 kW/m².

In one embodiment, the photosensitive film is stable over voltage, i.e., when subjected to a dark current bias, such as for example a dark current bias ranging from 0.1 V to 5 V, preferably from 0.5 V to 2.5 V, even more preferably from 1 V to 2V.

In one embodiment, the photosensitive film exhibits a quantum efficiency (QE) (i.e., an incident photon to converted electron ratio) ranging from about 20% to about 100%, preferably from about 30% to about 100%, more preferably from about 40% to about 100%, even more preferably from about 50% to about 100%.

In one embodiment, the photosensitive film exhibits a QE higher than about 20%, about 25%, about 30%, about 35%, about 40%, about 45%, about 50%, about 55%, about 60%, about 65%, about 70%, about 75%, about 80%, about 85%, about 90%, about 95% or more.

In one embodiment, the photosensitive film exhibits a dark current density (DCD) (i.e., an electric current that flows through the photosensitive film when no photons are entering said film) ranging from about 10⁻¹² A/cm² to about 10⁻⁶ A/cm², preferably from about 10⁻⁷ A/cm² to about 10⁻¹¹ A/cm², more preferably from about 10⁻⁷ A/cm² to about 10⁻¹⁰ A/cm².

In one embodiment, the photosensitive film exhibits a DCD of less than about 10⁻¹² A/cm², about 5·10⁻¹¹ A/cm⁻², about 10⁻¹¹ A/cm², about 5·10⁻¹⁰ A/cm², about 10⁻¹⁰ A/cm², about 5·10⁻⁹ A/cm², about 10⁻⁹ A/cm², about 5·10⁻⁸ A/cm², about 10⁻⁸ A/cm², about 5·10⁻⁷ A/cm², about 10⁻⁷ A/cm², about 5·10⁻⁶ A/cm², or about 10⁻⁶ A/cm².

In one embodiment, the photosensitive film exhibits a dark current density (DCD) (i.e., an electric current that flows through the photosensitive film when no photons are entering said film) ranging from about 1 e⁻/s to about 10000 e⁻/s, preferably from about 10 e⁻/s to about 1000 e⁻/s, more preferably from about 100 e⁻/s to about 500 e⁻/s.

In one embodiment, the photosensitive film exhibits a DCD of less than about 1 e⁻/s, about 50 e⁻/s, about 100 e⁻/s, about 150 e⁻/s, about 200 e⁻/s, about 225 e⁻/s, about 250 e⁻/s, about 275 e⁻/s, about 300 e⁻/s, about 325 e⁻/s, about 350 e⁻/s, about 400 e⁻/s, about 500 e⁻/s, about 1000 e⁻/s, or about 10000 e⁻/s.

In one embodiment, the stability of the photosensitive film can be assessed by measuring the quantum efficiency (QE) and/or the dark current density (DCD) of said photosensitive film.

Methods for measuring the quantum efficiency (QE) and/or the dark current density (DCD) of a photosensitive film are well known to the one skilled in the art.

In one embodiment, the photosensitive film is considered as stable if the absorbance at 450 nm or 600 nm does not decrease (by more than 50%, preferably 40%, 30%, 25%, 20%, 15%, 10%, 5%, 4%, 3%, 2%, 1%, or 0%) over time, the excitonic peak wavelength does not shift (by more than 5 nm, 10 nm or 15 nm), and/or the FWHM does not increase (by more than 5 nm, 10 nm or 15 nm) over time.

In one embodiment, the photosensitive film is considered as stable if the quantum efficiency (QE) of said film does not decrease over time and/or if the dark current density (DCD) of said film does not increase over time.

In one embodiment, the photosensitive film is considered as stable if the quantum efficiency (QE) of said film does not decrease by more than 50%, 40%, 30%, 25%, 20%, 15%, 10%, 5%, 1%, or 0% over time, such as for example:
over a time period ranging from 1 minute to 60 minutes, from 5 minutes to 30 minutes, or from 5 minutes to 15 minutes;
over a time period ranging from 1 hour to 168 hours, from 1 hour to 100 hours, from 1 hour to 72 hours, from 1 hour to 48 hours, from 1 hour to 24 hours, from 1 hour to 12 hours;
over a time period ranging from 1 day to 90 days, from 7 days to 60 days, from 1 day to 30 days, or from 1 day to 15 days;
over a time period ranging from 1 week to 52 weeks, from 4 weeks to 24 weeks, or from 4 weeks to 12 weeks; or
over a time period ranging from 1 month to 60 months, from 1 month to 36 months, from 1 month to 24 months, from 6 months to 24 months, or from 6 months to 12 months.

In one embodiment, the photosensitive film is considered as stable if the dark current density (DCD) of said film does not increase by more than about 0%, preferably about 1%, about 5%, about 10%, about 15%, about 20%, about 25%, about 30%, about 40%, or about 50% over time, such as for example:
over a time period ranging from 1 minute to 60 minutes, from 5 minutes to 30 minutes, or from 5 minutes to 15 minutes;
over a time period ranging from 1 hour to 168 hours, from 1 hour to 100 hours, from 1 hour to 72 hours, from 1 hour to 48 hours, from 1 hour to 24 hours, from 1 hour to 12 hours;
over a time period ranging from 1 day to 90 days, from 7 days to 60 days, from 1 day to 30 days, or from 1 day to 15 days;
over a time period ranging from 1 week to 52 weeks, from 4 weeks to 24 weeks, or from 4 weeks to 12 weeks; or
over a time period ranging from 1 month to 60 months, from 1 month to 36 months, from 1 month to 24 months, from 6 months to 24 months, or from 6 months to 12 months.

In one embodiment, the photosensitive film is considered as stable if it meets at least one stability test requirement.

Tests to assess the stability of a photosensitive film are well known in the art. Examples of such test include, but are not limited to, High-Temperature Operating Life test (HTOL), Low-Temperature Operating Life test (LTOL), Temperature Cycling test (TCT), Thermal Shock test (TST), Pressure Cooker test (PCT), Temperature and Humidity Bias test (THB), Highly Accelerated Stress test (HAST), High-Temperature Storage test (HTS), Low-Temperature Storage test (LTS), Temperature & Humidity test (THS), High Fault Coverage Life test, Salt Spray test (SALT), biased Highly Accelerated Stress test (HAST), unbiased Highly Accelerated Stress test (HAST) and the like.

In one embodiment, the photosensitive film is considered as stable if it meets the requirements of:
at least one of the stability tests “Test G-1” to “Test G-30”, as defined hereafter;
at least one of the stability tests “Test H-1” to “Test H-30”, as defined hereafter;
at least one of the stability tests “Test I-1” to “Test 1-30”, as defined hereafter;
at least one of the stability tests “Test J-1” to “Test J-30”, as defined hereafter;
at least one of the stability tests “Test K-1” to “Test K-30”, as defined hereafter;
at least one of the stability tests “Test L-1” to “Test L-30”, as defined hereafter;
at least one of the stability tests “Test M-1” to “Test M-30”, as defined hereafter;
at least one of the stability tests “Test N-1” to “Test N-30”, as defined hereafter.

Tests consist in measuring the stability of the photosensitive film under high thermal stress conditions for 12 hours (Tests G), for 24 hours (Tests H), for 36 hours (Tests I), for 48 hours (Tests J), for 60 hours (Tests K), for 72 hours (Tests L), for 84 hours (Tests M), for 96 hours (Tests N), in absence or in presence of a light stress (10 W/m²) and/or in absence or in presence of a dark current bias stress (2V).

Tests G to N are described in Table 2 below.

TABLE 2
Tests G to N

| | Light | DC | | | | | | | | |
|---|---|---|---|---|---|---|---|---|---|---|
| | stress | bias | 12 h | 24 h | 36 h | 48 h | 60 h | 72 h | 84 h | 96 h |
| 60° C. | yes | no | Test | Test | Test | Test | Test | Test | Test | Test |
| | | | G-1 | H-1 | I-1 | J-1 | K-1 | L-1 | M-1 | N-1 |
| | no | yes | Test | Test | Test | Test | Test | Test | Test | Test |
| | | | G-2 | H-2 | I-2 | J-2 | K-2 | L-2 | M-2 | N-2 |
| | yes | yes | Test | Test | Test | Test | Test | Test | Test | Test |
| | | | G-3 | H-3 | I-3 | J-3 | K-3 | L-3 | M-3 | N-3 |
| 70° C. | yes | no | Test | Test | Test | Test | Test | Test | Test | Test |
| | | | G-4 | H-4 | I-4 | J-4 | K-4 | L-4 | M-4 | N-4 |
| | no | yes | Test | Test | Test | Test | Test | Test | Test | Test |
| | | | G-5 | H-5 | I-5 | J-5 | K-5 | L-5 | M-5 | N-5 |
| | yes | yes | Test | Test | Test | Test | Test | Test | Test | Test |
| | | | G-6 | H-6 | I-6 | J-6 | K-6 | L-6 | M-6 | N-6 |
| 80° C. | yes | no | Test | Test | Test | Test | Test | Test | Test | Test |
| | | | G-7 | H-7 | I-7 | J-7 | K-7 | L-7 | M-7 | N-7 |
| | no | yes | Test | Test | Test | Test | Test | Test | Test | Test |
| | | | G-8 | H-8 | I-8 | J-8 | K-8 | L-8 | M-8 | N-8 |
| | yes | yes | Test | Test | Test | Test | Test | Test | Test | Test |
| | | | G-9 | H-9 | I-9 | J-9 | K-9 | L-9 | M-9 | N-9 |
| 90° C. | yes | no | Test | Test | Test | Test | Test | Test | Test | Test |
| | | | G-10 | H-10 | I-10 | I-10 | K-10 | L-10 | M-10 | N-10 |
| | no | yes | Test | Test | Test | Test | Test | Test | Test | Test |
| | | | G-11 | H-11 | I-11 | J-11 | K-11 | L-11 | M-11 | N-11 |
| | yes | yes | Test | Test | Test | Test | Test | Test | Test | Test |
| | | | G-12 | H-12 | I-12 | J-12 | K-12 | L-12 | M-12 | N-12 |
| 100° C. | yes | no | Test | Test | Test | Test | Test | Test | Test | Test |
| | | | G-13 | H-13 | I-13 | J-13 | K-13 | L-13 | M-13 | N-13 |
| | no | yes | Test | Test | Test | Test | Test | Test | Test | Test |
| | | | G-14 | H-14 | I-14 | J-14 | K-14 | L-14 | M-14 | N-14 |
| | yes | yes | Test | Test | Test | Test | Test | Test | Test | Test |
| | | | G-15 | H-15 | I-15 | J-15 | K-15 | L-15 | M-15 | N-15 |
| 110° C. | yes | no | Test | Test | Test | Test | Test | Test | Test | Test |
| | | | G-16 | H-16 | I-16 | J-16 | K-16 | L-16 | M-16 | N-16 |
| | no | yes | Test | Test | Test | Test | Test | Test | Test | Test |
| | | | G-17 | H-17 | I-17 | J-17 | K-17 | L-17 | M-17 | N-17 |
| | 10 W/m² | yes | Test | Test | Test | Test | Test | Test | Test | Test |
| | | | G-18 | H-18 | I-18 | J-18 | K-18 | L-18 | M-18 | N-18 |
| 120° C. | 10 W/m² | no | Test | Test | Test | Test | Test | Test | Test | Test |
| | | | G-19 | H-19 | I-19 | J-19 | K-19 | L-19 | M-19 | N-19 |
| | no | yes | Test | Test | Test | Test | Test | Test | Test | Test |
| | | | G-20 | H-20 | I-20 | J-20 | K-20 | L-20 | M-20 | N-20 |
| | 10 W/m² | yes | Test | Test | Test | Test | Test | Test | Test | Test |
| | | | G-21 | H-21 | I-21 | J-21 | K-21 | L-21 | M-21 | N-21 |
| 130° C. | 10 W/m² | no | Test | Test | Test | Test | Test | Test | Test | Test |
| | | | G-22 | H-22 | I-22 | J-22 | K-22 | L-22 | M-22 | N-22 |
| | no | yes | Test | Test | Test | Test | Test | Test | Test | Test |
| | | | G-23 | H-23 | I-23 | J-23 | K-23 | L-23 | M-23 | N-23 |
| | 10 W/m² | yes | Test | Test | Test | Test | Test | Test | Test | Test |
| | | | G-24 | H-24 | I-24 | J-24 | K-24 | L-24 | M-24 | N-24 |
| 140° C. | 10 W/m² | no | Test | Test | Test | Test | Test | Test | Test | Test |
| | | | G-25 | H-25 | I-25 | J-25 | K-25 | L-25 | M-25 | N-25 |
| | no | yes | Test | Test | Test | Test | Test | Test | Test | Test |
| | | | G-26 | H-26 | I-26 | J-26 | K-26 | L-26 | M-26 | N-26 |
| | 10 W/m² | yes | Test | Test | Test | Test | Test | Test | Test | Test |
| | | | G-27 | H-27 | I-27 | J-27 | K-27 | L-27 | M-27 | N-27 |
| 150° C. | 10 W/m² | no | Test | Test | Test | Test | Test | Test | Test | Test |
| | | | G-28 | H-28 | I-28 | J-28 | K-28 | L-28 | M-28 | N-28 |
| | no | yes | Test | Test | Test | Test | Test | Test | Test | Test |
| | | | G-29 | H-29 | I-29 | J-29 | K-29 | L-29 | M-29 | N-29 |
| | 10 W/m² | yes | Test | Test | Test | Test | Test | Test | Test | Test |
| | | | G-30 | H-30 | I-30 | J-30 | K-30 | L-30 | M-30 | N-30 |

It is considered that the photosensitive film is stable if:
the quantum efficiency (QE) of said film does not decrease, and/or
the dark current density (DC) of said film does not increase,
   in conditions wherein said photosensitive film is exposed:
for a period of time of 12, 24, 36, 48, 60, 72, 84 or 96 hours,
to a thermal stress of −20° C., 5° C., 15° C., 60° C., 70° C., 80° C., 90° C., 100° C., 110° C., 120° C., 130° C., 140° C. or 150° C.,
in absence or in presence of a light stress (10 W/m²), and
in absence or in presence of a dark current bias stress (2V),
   according to any one of the tests G to N as described above.

In one embodiment, the requirements of any one of the tests G to N as described above are met if the quantum efficiency (QE) of the photosensitive film measured after the test has not decreased by more than 50%, preferably 40%, 30%, 25%, 20%, 15%, 10%, 5%, 1%, or 0%, as compared to the quantum efficiency (QE) of the photosensitive film measured before the test.

In one embodiment, the requirements of any one of the tests G to N as described above are met if the dark current density (DCD) of the photosensitive film measured after the test has not increased by more than about 0%, preferably about 5%, about 10%, about 15%, about 20%, about 25%, about 30%, about 40%, or about 50%, as compared to the dark current density (DC) of the photosensitive film measured before the test.

In one embodiment, the photosensitive film has an electrical conductivity in standard conditions ranging from about 1×10⁻²⁰ to about 10⁷ S/m, preferably from about 1×10⁻¹⁵ to about 5 S/m, more preferably from about 1×10⁻⁷ to about 1 S/m.

The electrical conductivity of the photosensitive film may be measured, e.g., with an impedance spectrometer.

In one embodiment, the photosensitive film has an electron mobility in standard conditions ranging from about 0.01 cm²/(V·s) to about 1000 cm²/(V·s), preferably from about 0.1 cm²/(V·s) to about 1000 cm²/(V·s), more preferably from about 1 cm²/(V·s) to about 1000 cm²/(V·s), even more preferably from 1 cm²/(V·s) to about 10 cm²/(V·s).

The electron mobility of the photosensitive film may be measured, e.g., using the Hall effect, with a field-effect transistor (FET), by non-contact laser photo-reflectance or from time-resolved terahertz probe.

In one embodiment, the photosensitive film has a uniformity value ranging from 0.1% to 5%, preferably ranging from 0.1% to 2%, more preferably ranging from 0.1% to 51%. The uniformity of a film refers to the thickness deviation over the whole film area.

In one embodiment, the light-sensitive material further comprises or consists of at least one host material. The at least one host material protects the particles from molecular oxygen, ozone, water and/or high temperature. Therefore, deposition of a supplementary protective layer on top of said light-sensitive material is not compulsory, which can save time, money and loss of absorbance or luminescence.

In one embodiment, the at least one host material is free of oxygen. In one embodiment, the at least one host material is free of water.

In one embodiment, the at least one host material is optically transparent. In one embodiment, the at least one host material is optically transparent at wavelengths where the particles are absorbing.

In one embodiment, the light-sensitive material comprises at least two host materials. In this embodiment, the host materials may be different or identical.

In one embodiment, the particles are uniformly dispersed in the host material.

In one embodiment, the loading charge of particles in the light-sensitive material is ranging from 0.01% to 99%, preferably from 0.1% to 75%, more preferably from 0.5% to 50%, even more preferably from 1% to 10%.

In one embodiment, the particles have a packing fraction in the light-sensitive material ranging from 0.01% to 95%, preferably from 0.1% to 75%, more preferably from 0.5% to 50%, even more preferably from 1% to 10%.

In one embodiment, the particles are separated by the at least one host material. In this embodiment, the particles can be individually evidenced, e.g., by conventional microscopy, transmission electron microscopy, scanning transmission electron microscopy, scanning electron microscopy, or fluorescence scanning microscopy.

In one embodiment, the light-sensitive material does not comprise optically transparent void regions. In particular, the light-sensitive material does not comprise void regions surrounding the particles.

In one embodiment, the host material comprises or consists of a polymeric host material, an inorganic host material, or a mixture thereof.

In one embodiment, the polymeric host material may be PMMA; poly(lauryl methacrylate); glycolized poly(ethylene terephthalate); poly(maleic anhydride-altoctadecene); a fluorinated polymer layer, such as, e.g., an amorphous fluoropolymer (such as for example CYTOP™), PVDF, or a derivative of PVDF; silicon-based polymer; PET; PVA; or mixture thereof.

The advantage of amorphous fluoropolymer is its transparency and the low refractive index.

In one embodiment, the polymeric host material may be a polymerized solid made from alpha-olefins, dienes (such as, e.g., butadiene and chloroprene), styrene, alpha-methyl styrene and the like, heteroatom substituted alpha-olefins (such as, e.g., vinyl acetate), vinyl alkyl ethers (such as, e.g., ethyl vinyl ether, vinyltrimethylsilane, vinyl chloride), tetrafluoroethylene, chlorotrifiuoroethylene, cyclic and polycyclic olefin compounds (such as, e.g., cyclopentene, cyclohexene, cycloheptene, cyclooctene, and cyclic derivatives up to C₂₀), polycyclic derivates (such as, e.g., norbornene and similar derivatives up to C₂₀), cyclic vinyl ethers (such as, e.g., 2,3-dihydrofuran, 3,4-dihydropyran and similar derivatives), allylic alcohol derivatives (such as, e.g., vinylethylene carbonate), disubstituted olefins (such as, e.g., maleic and fumaric compounds, for example, maleic anhydride, diethylfumarate and the like), and mixture thereof.

Examples of inorganic host material include, but are not limited to, metals, halides, chalcogenides, phosphides, sulfides, metalloids, metallic alloys, ceramics (such as, e.g., oxides, carbides, or nitrides) and mixtures thereof.

In one embodiment, the halide host material is selected from the group comprising or consisting of BaF₂, LaF₃, CeF₃, YF₃, CaF₂, MgF₂, PrF₃, AgCl, MnCl₂, NiCl₂, Hg₂Cl₂, CaCl₂, CsPbCl₃, AgBr, PbBr₃, CsPbBr₃, AgI, CuI, PbI, HgI₂, BiI₃, CH₃NH₃PbI₃, CsPbI₃, FAPbBr₃ (with FA formamidinium), or a mixture thereof.

In one embodiment, the chalcogenide host material is selected from the group comprising or consisting of CdO, CdS, CdSe, CdTe, ZnO, ZnS, ZnSe, ZnTe, HgO, HgS, HgSe, HgTe, CuO, Cu₂O, CuS, Cu₂S, CuSe, CuTe, Ag₂O, Ag₂S, Ag₂Se, Ag₂Te, Au₂O₃, Au₂S, PdO, PdS, Pd₄S, PdSe, PdTe, PtO, PtS, PtS₂, PtSe, PtTe, RhO₂, Rh₂O₃, RhS₂, Rh₂S₃, RhSe₂, Rh₂Se₃, RhTe₂, IrO₂, IrS₂, Ir₂S₃, IrSe₂, IrTe₂, RuO₂, RuS₂, OsO, OsS, OsSe, OsTe, MnO, MnS, MnSe, MnTe, ReO₂, ReS₂, Cr₂O₃, Cr₂S₃, MoO₂, MoS₂, MoSe₂, MoTe₂, WO₂, WS₂, WSe₂, V₂O₅, V₂S₃, Nb₂O₅, NbS₂, NbSe₂, HfO₂, HfS₂, TiO₂, ZrO₂, ZrS₂, ZrSe₂, ZrTe₂, Sc₂O₃, Y₂O₃, Y₂S₃, SiO₂, GeO₂, GeS, GeS₂, GeSe, GeSe₂, GeTe, SnO₂, SnS, SnS₂, SnSe, SnSe₂, SnTe, PbO, PbS, PbSe, PbTe, MgO, MgS, MgSe, MgTe, CaO, CaS, SrO, Al₂O₃, Ga₂O₃, Ga₂S₃, Ga₂Se₃, In₂O₃, In₂S₃, In₂Se₃, In₂Te₃, La₂O₃, La₂S₃, CeO₂, CeS₂, Pr₆O₁₁, Nd₂O₃, NdS₂, La₂O₃, Tl₂O, Sm₂O₃, SmS₂, Eu₂O₃, EuS₂, Bi₂O₃, Sb₂O₃, PoO₂, SeO₂, Cs₂O, Tb₄O₇, TbS₂, Dy₂O₃, Ho₂O₃, Er₂O₃, ErS₂, Tm₂O₃, Yb₂O₃, Lu₂O₃, CuInS₂, CuInSe₂, AgInS₂, AgInSe₂, Fe₂O₃, Fe₃O₄, FeS, FeS₂, Co₃S₄, CoSe, Co₃O₄, NiO, NiSe₂, NiSe, Ni₃Se₄, Gd₂O₃, BeO, TeO₂, Na₂O, BaO, K₂O, Ta₂O₅, Li₂O, Tc₂O₇, As₂O₃, B₂O₃, P₂O₅, P₂O₃, P₄O₇, P₄O₈, P₄O₉, P₂O₆, PO, or a mixture thereof.

In one embodiment, the oxide host material is selected from the group comprising or consisting of SiO₂, Al₂O₃, TiO₂, ZrO₂, ZnO, MgO, SnO₂, Nb₂O₅, CeO₂, BeO, IrO₂, CaO, Sc₂O₃, NiO, Na₂O, BaO, K₂O, PbO, Ag₂O, V₂₀₅, TeO₂, MnO, B₂O₃, P₂O₅, P₂₀₃, P₄₀₇, P₄₀₈, P₄₀₉, P₂₀₆, PO, GeO₂, As₂O₃, Fe₂O₃, Fe₃O₄, Ta₂O₅, Li₂O, SrO, Y₂O₃, HfO₂, WO₂, MoO₂, Cr₂O₃, Tc₂O₇, ReO₂, RuO₂, Co₃O₄, OsO, RhO₂, Rh₂O₃, PtO, PdO, CuO, Cu₂O, Au₂O₃, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, and a mixture thereof.

In one embodiment, the host material comprises or consists of a thermal conductive material, wherein said thermal conductive material includes, but is not limited to, Al₂O₃, Ag₂O, Cu₂O, CuO, Fe₃O₄, FeO, SiO₂, PbO, CaO, MgO, ZnO, SnO₂, TiO₂, BeO, CdS, ZnS, ZnSe, CdZnS, CdZnSe, Au, Na, Fe, Cu, Al, Ag, Mg, mixed oxides, mixed oxides thereof or a mixture thereof.

In one embodiment, the host material comprises organic molecules in small amounts of about 0 mole %, about 1 mole %, about 5 mole %, about 10 mole %, about 25 mole %, about 50 mole % or more, relative to the majority element of said host material.

Without being bound by any theory, the Applicant believes that the light-sensitive material can be described as a core/shell/shell particle.

Indeed, after drying, it is believed that the metal halide binder yields to a shell (or a crown) around the particle.

In one embodiment, the core/shell/shell particles comprise:
a core comprising a material selected from the group of PbS, InAs, Ag₂S, Ag₂Se, HgTe, HgCdTe, CdS, PbSe, PbCdS, PbCdSe, PbTe, HgS, HgSe, InGaAs, InGaP, GaAs, CuInS₂, CuInSe₂;
a first shell comprising a material selected from the group of HgS, HgSe, CdS, PbS, CdTe, CdSe, CdZnS, CdZnSe, ZnS and ZnSe; and
a second shell comprising a metal halide selected from the group of ZnX₂, PbX₂, CdX₂, SnX₂, HgX₂, BiX₃, CsPbX₃, CsX, NaX, KX, LiX, CsPbX₃ et HC(NH₂)₂PbX₃, CH₃NH₃PbX₃, or a mixture thereof, wherein X is selected from Cl, Br, I, F or a mixture thereof.

In one embodiment, the core/shell/shell particles comprise:
a core comprising a material selected from the group of PbS, InAs, Ag₂S, Ag₂Se, HgTe, HgCdTe, CdS, PbSe, PbCdS, PbCdSe, PbTe, HgS, HgSe, InGaAs, InGaP, GaAs, CuInS₂, CuInSe₂;
a first shell comprising a first metal halide selected from the group of ZnX₂, PbX₂, CdX₂, SnX₂, HgX₂, BiX₃, CsPbX₃, CsX, NaX, KX, LiX, CsPbX₃ et HC(NH₂)₂PbX₃, CH₃NH₃PbX₃, or a mixture thereof, wherein X is selected from Cl, Br, I, F or a mixture thereof; and
a second shell comprising a second metal halide selected from the group of ZnX₂, PbX₂, CdX₂, SnX₂, HgX₂, BiX₃, CsPbX₃, CsX, NaX, KX, LiX, CsPbX₃ et HC(NH₂)₂PbX₃, CH₃NH₃PbX₃, or a mixture thereof, wherein X is selected from Cl, Br, I, F or a mixture thereof.

In a preferred embodiment illustrated partially in FIG. 3, the core/shell/shell particles include, but are not limited to:
InAs/ZnS/ZnX₂ (in particular ZnCl₂), InAs/ZnSe/ZnX₂ (in particular InAs/ZnSe/ZnCl₂), InAs/CdS/CdX₂, InAs/CdSe/CdX₂,
PbS/CsI—PbI₂/CsPbI₃, PbS/PbI₂/CsPbI₃, PbS/PbI₂/CsI, PbS/NaI/CsPbI₃, PbS/CsI—NaI—CsPbI₃, PbS/CdS/CdX₂, PbS/CdSe/CdX₂, PbS/PbX₂/ZX such as for example PbS/PbI₂/CsI, PbS/CsI—NaI—PbI₂/CsPbI₃, PbS/CsI—NaI/CsPbI₃, PbS/PbX₂/ZPbX₃, PbS/ZPbX₃/PbX₂,
PbSe/CdS/CdX₂, PbSe/CdSe/CdX₂, PbSe/PbS/PbX₂,
HgS/CdS/CdX₂, HgS/CdSe/CdX₂,
HgSe/CdS/CdX₂, HgSe/CdSe/CdX₂, HgSe/CdTe/CdX₂, HgSe/HgS/HgX₂,
HgTe/CdS/CdX₂, HgTe/CdSe/CdX₂, HgTe/CdTe/CdX₂, HgTe/HgS/HgX₂, HgTe/HgSe/HgX₂,
   wherein X=Cl, Br, I, F or a mixture thereof, and Z=Li, Na, K, Cs or a mixture thereof.

In one embodiment, the core has a size ranging from 2 nm to 100 nm, preferably from 2 nm to 50 nm, more preferably from 2 nm to 20 nm, even more preferably from 2 nm to 10 nm.

In one embodiment, the first and/or second shell has a thickness ranging from 0.1 nm to 50 nm, preferably from 0.1 nm to 20 nm, more preferably from 0.1 nm to 10 nm, even more preferably from 0.1 nm to 5 nm, most preferably from 0.1 nm to 0.5 nm.

In one embodiment, the first shell covers partially or totally the core. In one embodiment, the second shell covers partially or totally the first shell.

In one embodiment, the core/shell/shell particles may comprise:
(i) a core comprising at least one first material,
(ii) a first shell coating partially or totally the core, comprising at least one second material, and
(iii) a second shell coating partially or totally the first shell, comprising at least one third material,
wherein the valence band energy level of the first material is at least equal or higher than the valence band energy level of the second material, and the conduction band energy level of the first material is at least equal or lower than the conduction band energy level of the at least one second material.

In one embodiment, the valence band energy level and conduction band energy level are defined at a standard temperature and pressure of 273.15 K and 105 Pa respectively.

Another object of the present invention relates to a support, supporting an ink, a light-sensitive material, or a photosensitive film of the invention.

In one embodiment, the support is a substrate as described hereinabove.

In one embodiment, the support supports at least one light-sensitive material (preferably, at least one photosensitive film) comprising at least one population of particles, at least two populations od particles or a plurality of populations of particles. In the present application, a population of particles is defined by the maximum absorption wavelength.

In one embodiment, the support supports at least one, at least two or a plurality of light-sensitive materials (preferably, photosensitive films), each comprising one population of particles.

In one embodiment, the at least one light-sensitive material (preferably, photosensitive film) on a support is encapsulated into a multilayered system. In one embodiment, the multilayer system comprises or consists of at least two, at least three layers. In a particular embodiment, the multilayered system may further comprise at least one auxiliary layer (also called capping layer or protective layer, defined hereinabove).

The present invention also relates to a device, comprising at least one light-sensitive material or photosensitive film of the invention.

In one embodiment, a first device, comprises:
at least one light-sensitive material of the invention; and
a plurality of electrical connections bridging said light-sensitive material;
   wherein the first device is a photoconductor device, a photodetector device, a photodiode device or a phototransistor.

In one embodiment, the light-sensitive material is a photoabsorptive film.

In one embodiment, the at least one photoabsorptive film is positioned such that there is an increased conductivity between the electrical connections and across the at least one photoabsorptive film, in response to illumination of the at least one photoabsorptive film with light having at a wavelength ranging even more preferably from about 750 nm to about 3 μm, most preferably from about 750 nm to about 1.4 μm, from about 750 nm to about 1000 nm, preferably from about 800 nm to about 1000 nm, more preferably from about 850 nm to about 1000 nm, even more preferably from about 900 nm to about 1000 nm, most preferably from about 925 nm to about 975 nm, most preferably with light having at a wavelength of about 940 nm.

In one embodiment, the photoconductor, photodetector, photodiode or phototransistor can be selected from the group comprising or consisting of a charge-coupled device (CCD), a luminescent probe, a laser, a thermal imager, a night-vision system and a photodetector.

In one embodiment, the photoconductor, photodetector, photodiode or phototransistor of the invention comprises or consists of a first cathode, the first cathode being electronically coupled to a first photoabsorptive film, the first photoabsorptive film being coupled to a first anode.

In one embodiment, the transistor may be a dual (bottom and electrolytic) gated transistor comprising a thin photoabsorptive film on a support; electrodes such as a drain electrode, a source electrode and a top gate electrode; and an electrolyte. In this embodiment, the photoabsorptive film is deposited on top of a support and connected to the source and the drain electrodes; the electrolyte is deposited on top of said film and the top gate is on top of the electrolyte. The support may be a doped Si substrate.

In one embodiment, the photodetector is used as a flame detector.

In one embodiment, the photodetector allows bicolor detection or multicolor detection.

In one embodiment, the photodetector allows bicolor detection and one of the wavelengths is ranging from 750 nm to 12 μm, more preferably from 750 nm to 1.5 μm, most preferably from 750 nm to 1 μm, most preferably from 900 nm to 1 μm, even most preferably one of the wavelengths is centered around about 940 nm.

The present invention also relates to a second device comprising:
at least one substrate;
at least one electronic contact layer;
at least one electron transport layer; and
at least one photoactive layer comprising at least one light-sensitive material of the invention;
   wherein said device has a vertical geometry.

The vertical geometry allows a shorter travel distance for the charge carriers compared to a planar geometry, thus enhancing the transport properties of the second device. A vertical geometry refers to a photodiode geometry—or to the structure of tiramisu—while a planar geometry refers to a photoconductive geometry. The photodiode geometry allows a lower operating bias, thus reducing the dark current compared to photoconductive geometry.

In one embodiment, the second device is a photodiode, a diode, a solar cell, or a photoconductor.

In one embodiment, the second device comprises at least two electronic contact layers: at least one bottom electrode and one top electrode.

In one embodiment, the at least two electronic contact layers are interdigitated electrodes. In particular, the at least two electronic contact layers are pre-patterned interdigitated electrodes. In this embodiment, the second device comprises:
at least one substrate;
a first electronic contact layer;
at least one electron transport layer;
at least one photoactive layer; and
a second electronic contact layer.

In one embodiment, the second device further comprises of at least one hole transport layer. In this embodiment, the second device comprises:
at least one substrate;
a first electronic contact layer;
at least one electron transport layer;
at least one photoactive layer;
at least one hole transport layer; and
a second electronic contact layer.

In one embodiment, the second device further comprises at least one encapsulating layer deposited on top of the other layers. The encapsulation with the at least one encapsulating layer enhances the stability of the device under air and/or humidity conditions, prevents the degradation of said device due to air and/or humidity exposure. Said encapsulation is not detrimental to the transport and/or optical properties of the device and helps preserving said transport and/or optical properties of the device upon air and/or humidity exposure.

In one embodiment, the second device comprises a plurality of encapsulating layers, preferably three encapsulating layers.

In one embodiment, the layers are successively overlaid on the substrate:
the electronic contact layer (in particular the first electronic contact layer) is overlaid on the substrate;
the electron transport layer is overlaid on the electronic contact layer;
the photoactive layer is overlaid on the electron transport layer;
the hole transport layer is overlaid on the photoactive layer;
the second electronic contact layer is overlaid on the hole transport layer or the photoactive layer; and/or
the at least one encapsulating layer is overlaid on the second electronic contact layer.

In one embodiment, the time response of the second device is faster while using a nanotrench geometry compared to μm spaced electrodes.

In one embodiment, the electronic contact layer is an electrode.

In one embodiment, the electronic contact layer is a metal contact.

In one embodiment, the second device comprises contact pads connected to the at least two electronic contact layers.

In one embodiment, the second device comprises an additional adhesion layer between the substrate and the electronic contact layer to promote the adhesion of said electronic contact layer. In this embodiment, the additional adhesion layer comprises of consists of Ti or Cr.

In one embodiment, the additional adhesion layer has a thickness ranging from 1 nm to 20 nm, preferably from 1 nm to 10 nm, more preferably from 5 nm to 20 nm.

In one embodiment, the electronic contact layer comprises or consists of a transparent oxide.

In one embodiment, the electronic contact layer comprises or consists of a conductive oxide.

In one embodiment, the electronic contact layer comprises or consists of a transparent conductive oxide. Examples of transparent conductive oxide include, but are not limited to, ITO (indium tin oxide), AZO (aluminum doped zinc oxide) or FTO (fluor doped tin oxide).

In one embodiment, the electronic contact layer has a work function ranging from about ranging from about 5 eV to about 3 eV, preferably from 4.7 eV to 3 eV, more preferably from 4.5 eV to 3.5 eV.

In one embodiment, the electronic contact layer is partly or totally optically transparent in the infrared range.

In one embodiment, the electronic contact layer is partly or totally optically transparent in the near infrared range.

In one embodiment, the electronic contact layer is partly or totally optically transparent in the short-wave infrared range, i.e., from about 0.8 to about 2.5 μm.

In one embodiment, the electron transport layer has a transparency of at least about 30%, at least about 40%, at least about 50%, at least about 60%, at least about 70%, at least about 80%, preferably at least about 90%, more preferably at least about 95% in the infrared range, in the near infrared range, in the short wave infrared range.

In one embodiment, the electronic contact layer has a thickness ranging from 0.5 nm to 300 nm, preferably from 10 nm to 200 nm, more preferably from 10 nm to 100 nm.

A low thickness, i.e., the electronic contact layer being a thin layer, allows a weak absorption of said electronic contact layer in the infrared range, thus an optimal transmission to the photoactive layer. A low thickness enables better performances for the device.

In one embodiment, to build a partly transparent electronic contact layer, a thin layer of material (metal or metal oxide as described hereinabove) which thickness is below about 10 nm is coupled to a metallic grid which covers less than about 50% of the total electronic contact layer surface, preferably less than about 33% and more preferably less than about 25%.

In one embodiment, the electron transport layer is used to extract electrons from the photoactive layer.

In one embodiment, the electron transport layer has a thickness ranging from 1 nm to 1 μm, preferably from 50 nm to 750 nm, even more preferably from 100 nm to 500 nm, most preferably from 10 nm to 50 nm.

In one embodiment, the electron transport layer comprises or consists of at least one n-type polymer. Examples of n-type polymer include, but are not limited to, polyethylenimine (PEI), poly(sulfobetaine methacrylate) (PSBMA), amidoamine-functionalized polyfluorene (PFCON-C), or a mixture thereof.

In one embodiment, the electron transport layer comprises or consists of an inorganic material.

In one embodiment, the electron transport layer comprises or consists of an inorganic material such as fullerenes (C₆₀, C₇₀) or tris(8-hydroxyquinoline) aluminum (Alq₃), or a mixture thereof.

In one embodiment, the electron transport layer comprises or consists of a n-type oxide such as for example ZnO, aluminum doped zinc oxide (AZO), SnO₂, TiO₂, mixed oxides; or a mixture thereof.

In one embodiment, the electron transport layer has an electron mobility higher than about 10⁻⁴ cm²V⁻¹s⁻¹, about 10⁻³ cm²V⁻¹s⁻¹, about 10⁻² cm²V⁻¹s⁻¹, about 10⁻¹ cm²V⁻¹s⁻¹, about 1 cm²V⁻¹s⁻¹, about 10 cm²V⁻¹s⁻¹, about 20 cm²V⁻¹s⁻¹, about 30 cm²V⁻¹s⁻¹, about 40 cm²V⁻¹s⁻¹, or about 50 cm²V⁻¹s⁻¹.

In one embodiment, the hole transport layer comprises or consists of an inorganic material.

In one embodiment, the hole transport layer comprises or consists of a p-type oxide such as for example molybdenum trioxide MoO₃, vanadium pentoxide V₂O₅, tungsten trioxide WO₃, chromium oxide CrOₓ such as Cr₂O₃, rhenium oxide ReO₃, ruthenium oxide RuOₓ, cuprous oxide Cu₂O, cupric oxide CuO, CuO₂, Cu₂O₃, ZrO₂, NiOₓ, NiOₓ/MoOₓ, Al₂O₃/NiOₓ, wherein NiOₓ is NiO or Ni₂O₃, mixed oxides, or a mixture thereof wherein x is a decimal number ranging from 0 to 5.

In one embodiment, the hole transport layer comprises graphene oxide GO, copper iodide CuI, copper(I) thiocyanate CuSCN, or a mixture thereof.

In one embodiment, the hole transport layer comprises or consists of a p-type polymer such as for example poly(3-hexylthiophene) (P3HT), poly(3,4-ethylenedioxythiophene) (PEDOT), polystyrene sulfonate (PSS), poly(3,4-ethylenedioxythiophene):poly(4-styrenesulfonate) PEDOT:PSS, poly(9-vinylcarbazole) (PVK), N,N′-Bis(3-methylphenyl)-N,N′-diphenylbenzidine based-polymer, ammonium heptamolybdate (NH₄)₆Mo₇O₂₄.4H₂O, poly(4-butyl-phenyl-diphenyl-amine), N,N′-diphenyl-N,N′-bis(3-methylphenyl)-1,1′-diphenyl-4,4′-diamine, 4,4′,4″-tris(Ncarbazolyl)-triphenyl-amine (TCTA), 4,4′-bis(carbazole-9-yl)-biphenyl (CBP), vanadyl-phthalocyanine (VOPc), 4,4′,4′-tris(3-methylphenylphenylamino)triphenylamine, or a mixture thereof.

In one embodiment, the hole transport layer has a transparency higher than about 80%, preferably higher than about 90%, more preferably higher than about 95% in the infrared range, in the near infrared range, in the short-wave infrared range.

In one embodiment, the hole transport layer has a hole mobility higher than about 10⁻⁴ cm²V⁻¹s⁻¹, about 10⁻³ cm²V⁻¹s⁻¹, about 10⁻² cm²V⁻¹s⁻¹, about 10⁻¹ cm²V⁻¹s⁻¹, about 1 cm²V⁻¹s⁻¹, about 10 cm²V⁻¹s⁻¹, about 20 cm²V⁻¹s⁻¹, about 30 cm²V⁻¹s⁻¹, about 40 cm²V⁻¹s⁻¹, or about 50 cm²V⁻¹s⁻¹.

In one embodiment, the encapsulating layer is a capping layer as described hereinabove.

In one embodiment, the at least one encapsulating layer helps stabilizing the device so that said encapsulated device has air-stable properties.

In one embodiment, the at least one encapsulating layer covers and/or surrounds partially or totally the second electronic contact layer.

In one embodiment, the at least one encapsulating layer has a thickness ranging from 500 nm to 100 μm preferably from 50 nm to 500 nm, even more preferably from 100 to 400 nm, most preferably from 100 nm to 250 nm.

In one embodiment, the at least one encapsulating layer has a transparency higher than about 70%, preferably higher than about 85%, more preferably higher than about 90% in the infrared range, in the near infrared range, in the short wave infrared range, and/or in the mid wave infrared range.

In one embodiment, the at least one encapsulating layer is a stack of at least 3 layers, each of them behaving as a barrier for different molecular species or fluids (liquid or gas).

In one embodiment, the first encapsulating layer allows the device to have a flatten and smoothen surface.

In one embodiment, the first encapsulating layer behaves as a water repellant.

In one embodiment, the second encapsulating layer protects the photoactive layer and the device from O₂.

In one embodiment, the second encapsulating layer is a O₂ barrier.

In one embodiment, the third encapsulating layer protects the photoactive layer and the device from H₂O.

In one embodiment, the third encapsulating layer is a H₂O barrier.

In one embodiment, the at least one encapsulating layer is an inorganic layer. Examples of inorganic layer include, but are not limited to, ZnO, ZnS, ZnSe, Al₂O₃, SiO₂, TiO₂, ZrO₂, MgO, SnO₂, IrO₂, As₂S₃, As₂Se₃, or a mixture thereof.

In one embodiment, the at least one encapsulating layer comprises or consists of a wide band gap semiconductor material. Examples of wide band gap semiconductor material include, but are not limited to, CdS, ZnO, ZnS, ZnSe, or a mixture thereof.

In one embodiment, the at least one encapsulating layer comprises or consists of an insulating material. Examples of insulating material include, but are not limited to, SiO₂, HfO₂, Al₂O₃, or a mixture thereof.

In one embodiment, the at least one encapsulating layer is a polymer layer.

In one embodiment, the encapsulating layer comprises or consists of epoxy; a fluorinated polymer, such as, e.g., polyvinylidene fluoride (PVDF) or a derivative of PVDF; silicon based polymer, polyethylene terephthalate (PET), poly(methyl methacrylate) (PMMA), poly(lauryl methacrylate) (PMA), poly(maleic anhydride-alt-1-octadecene) (PMAO), glycolized poly(ethylene terephthalate), polyvinyl alcohol (PVA), or mixture thereof.

In one embodiment, the first encapsulating layer comprises poly(methyl methacrylate) (PMMA), poly(lauryl methacrylate) (PMA), poly(maleic anhydride-alt-1-octadecene) (PMAO) or a mixture thereof.

In one embodiment, the second encapsulating layer comprises polyvinyl alcohol (PVA).

In one embodiment, the third encapsulating layer comprises or consists of a fluorinated polymer, such as, e.g., polyvinylidene fluoride (PVDF) or a derivative of PVDF.

In one embodiment, the second device is an intraband photodiode.

In one embodiment illustrated in FIG. 4A, the second device 5 comprises a substrate 51, an ITO layer; a ZnO layer; a photosensitive film 6 comprising PbS quantum dots; a NiO layer, wherein NiOₓ is NiO or Ni₂O₃; and a gold layer; wherein the layers are successively overlaid on the substrate and on each other. In this embodiment, the NiOₓ layer has a thickness ranging from 2 nm to 100 nm, preferably from 10 nm to 30 nm; the photosensitive film has a thickness ranging from 200 nm to 800 nm, preferably from 300 nm to 500 nm; and the ZnO layer has a thickness ranging from 2 nm to 150 nm, preferably from 10 nm to 20 nm.

In one embodiment illustrated in FIG. 4B, the second device 5 comprises a substrate 51; a metallic layer; an oxide layer such as for example ZnO, TiO₂, or TiO₂/ZnO; a photosensitive film 6 comprising PbS quantum dots; a NiOₓ, NiOₓ/MoOₓ or Al₂O₃/NiOₓ layer, wherein NiOₓ is NiO or Ni₂O₃ and MoOₓ can be MoO₃; and a ITO or AZO layer; wherein the layers are successively overlaid on the substrate and on each other. In this embodiment, the NiOₓ, NiOₓ/MoOₓ or Al₂O₃/NiOₓ layer has a thickness ranging from 2 nm to 100 nm, preferably from 10 nm to 30 nm; the photosensitive film has a thickness ranging from 200 nm to 800 nm, preferably from 300 nm to 500 nm; and the oxide layer has a thickness ranging from 2 nm to 150 nm, preferably from 10 nm to 20 nm.

The following embodiments may apply to each of both devices of the invention.

In one embodiment, the device has a high carrier mobility.

In one embodiment, the device has a carrier mobility ranging from about 0.01 cm²/(V·s) to about 1000 cm²/(V·s), preferably from about 0.1 cm²/(V·s) to about 1000 cm²/(V·s), more preferably from about 1 cm²/(V·s) to about 1000 cm²/(V·s), even more preferably from 1 cm²/(V·s) to about 10 cm²/(V·s).

In one embodiment, the device has a carrier mobility higher than about 1 cm²V⁻¹s⁻¹, preferably higher than about 5 cm²V⁻¹s⁻¹, more preferably higher than about 10 cm²V⁻¹s⁻¹.

In one embodiment, the time response of the device is smaller than about 100 μs, more preferably smaller than about 10 μs and even more preferably smaller than about 1 μs, preferably smaller than about 100 ns, more preferably smaller than about 10 ns and even more preferably smaller than about 1 ns.

In a preferred embodiment, the time response of the device ranges from about 1 ns to about 200 ns, preferably from about 50 ns to about 200 ns, more preferably from 1 ns to 20 ns, most preferably from 1 ns to 10 ns.

In one embodiment, the device is dedicated to photodetection, in particular the device is dedicated to photodetection in the infrared spectrum.

In one embodiment, the device is coupled to a read-out circuit, such as for example a a CMOS read-out circuit.

In one embodiment, the light-sensitive material or photosensitive film is illuminated by the front side or by the back side (through a transparent substrate).

In one embodiment, the light-sensitive material or photosensitive film is connected to a read-out circuit.

In one embodiment, the light-sensitive material or photosensitive film is not directly connected to the electrodes.

In one embodiment, the light-sensitive material or photosensitive film has a photo response ranging from about 1 μA·W⁻¹ to about 1 kA·W⁻¹, from about 1 mA·W⁻¹ to about 50 A·W⁻¹, or from about 10 mA·W⁻¹ to about 10 A·W⁻¹.

In one embodiment, the light-sensitive material or photosensitive film has a bandwidth superior to 1 MHz, in conditions wherein the light-sensitive material or photosensitive film is illuminated with a light having at a wavelength ranging from about 750 nm to about 3 μm, from about 750 nm to about 1.4 μm, from about 750 nm to about 1000 nm, more preferably from about 900 nm to about 1000 nm, even more preferably from about 925 nm to about 975 nm, most preferably with a light having at a wavelength of about 940 nm.

In one embodiment, the time response of the light-sensitive material or photosensitive film under a pulse of light is smaller than about 100 μs, more preferably smaller than about 10 μs and even more preferably smaller than about 1 μs, preferably smaller than about 100 ns, more preferably smaller than about 10 ns and even more preferably smaller than about 1 ns.

In a preferred embodiment, the time response of the light-sensitive material or photosensitive film under a pulse of light ranges from about 1 ns to about 200 ns, preferably from about 50 ns to about 200 ns, more preferably from 1 ns to 20 ns, most preferably from 1 ns to 10 ns.

In one embodiment, the light-sensitive material or photosensitive film is conducting electrons and/or holes.

In one embodiment, the light-sensitive material or photosensitive film exhibit interband transition or intraband transition.

The present invention also relates to a system, preferably a photoconductor system, a photodetector system, a photodiode system or a phototransistor system, comprising:
a plurality of devices (preferably photoconductors, photodetectors, photodiodes or phototransistors) as described hereinabove; and
a read-out circuit electrically connected to the plurality of devices.

The present invention also relates to a system comprising:
at least one device as described hereinabove; and
at least one LED.
   wherein said device is an optoelectronic device.

In one embodiment, the optoelectronic device is selected from the group comprising or consisting of a display device, a diode, a light emitting diode (LED), a laser, a photodetector, a transistor, a supercapacitor, a barcode, a LED, a microLED, an array of LED, an array of microLED, and an IR camera.

In one embodiment, the LED is a blue LED (400 nm to 470 nm) such as for instance a gallium nitride-based diode, a UV LED (200 nm to 400 nm), a green LED (500 nm to 560 nm), or a red LED (750 to 850 nm).

In one embodiment, the LED is a GaN, GaSb, GaAs, GaAsP, GaP, InP, SiGe, InGaN, GaAlN, GaAlPN, AN, AlGaAs, AlGaP, AlGaInP, AlGaN, AlGaInN, ZnSe, Si, SiC, diamond, boron nitride diode.

In one embodiment, the LED is comprised in a smartphone or a tablet.

The present invention also relates to the use of the ink, light-sensitive material, photosensitive film, device or system of the invention.

In one embodiment, the ink, light-sensitive material, photosensitive film, device or system of the invention are used for their spectral selective properties. In particular, the ink, light-sensitive material, photosensitive film, device or system of the invention are used for their spectral selective properties in the SWIR (Short-Wavelength InfraRed) range of wavelengths.

In one embodiment, the ink, light-sensitive material, photosensitive film, device or system of the invention are comprised in an IR-absorbing coating.

In one embodiment, the ink, light-sensitive material, photosensitive film, device or system of the invention are used as an active layer in a photodetector.

In one embodiment, the ink, light-sensitive material, photosensitive film, device or system of the invention are comprised in an infrared camera, such as for example as the absorbing layer of an infrared camera.

In one embodiment, the ink, light-sensitive material, photosensitive film, device or system of the invention are used for face recognition, objects detection, industrial imaging, imaging for process monitoring and quality control, lidar (also called LIDAR, LiDAR, and LADAR), plant disease detection, or object detection. In this embodiment, the ink, light-sensitive material, photosensitive film, device or system of the invention are used with a connected apparatus (such as for example a smartphone, a computer, tablet) capable of detecting an object or a face.

### BRIEF DESCRIPTION OF THE DRAWINGS

FIG. 1 is a schematic representation of various shapes (spheres and plates) and structure (homostructure, core/shell, core/crown, dot in plate) of semi-conductive nanoparticles.

FIG. 2 is a schematic representation of an ink deposited and annealed according to the method of the invention and comprising particles 7 bound together by a metal halide binder 8.

FIG. 3 is a schematic representation of core/shell/shell particles.

FIG. 4A illustrates a device with vertical geometry according to an embodiment.

FIG. 4B illustrates a device with vertical geometry according to an embodiment.

FIG. 5 shows the normalized absorption spectrum of InAs/ZnSe quantum dots (dashed line) and an ink comprising InAs/ZnSe quantum dots and ZnCl₂ binder (solid line). Abscissa axis is wavelength (nm), and ordinate axis is normalized absorbance (a.u).

FIG. 6A shows X-rays diffractogram of a film comprising PbS quantum dots and a mixture of CsI and PbI₂ as the metal halide binder after annealing depending on annealing time (dashed peaks: PbS rock salt; from bottom to top diffractogram: 0-36 min, 36 min-1 h 12, 1 h 12-1 h 48, 1 h 48-2 h 24, 2 h 24-3 h). Abscissa axis is 20, and ordinate axis is counts (a.u).

FIG. 6B shows normalized absorption spectra of a film comprising PbS quantum dots and a mixture of CsI and PbI₂ as the metal halide binder before annealing (dashed line) after annealing (solid line). Abscissa axis is wavelength (nm), and ordinate axis is normalized absorbance (a.u).

FIG. 7A shows IV curves of a film comprising PbS quantum dots and a mixture of CsI and PbI₂ as the metal halide binder before annealing (solid line=dark, dashed line=1 mW/cm², dash-dotted line=2 mW/cm²). Abscissa axis is applied voltage (V), and ordinate axis is current density (A/cm²).

FIG. 7B shows IV curves of a film comprising PbS quantum dots and a mixture of CsI and PbI₂ as the metal halide binder after annealing (solid line=dark, dashed line=1 mW/cm², dash-dotted line=2 mW/cm²). Abscissa axis is applied voltage (V), and ordinate axis is current density (A/cm²).

FIG. 8A shows x-rays diffractograms of a film comprising PbS quantum dots before and after annealing (dashed peaks: PbS rock salt; from bottom to top diffractogram: before annealing, after annealing). Abscissa axis is 20, and ordinate axis is counts (a.u).

FIG. 8B shows normalized absorption spectra of a film comprising PbS before (dashed line) and after annealing (solid line). Abscissa axis is wavelength (nm), and ordinate axis is normalized absorbance (a.u).

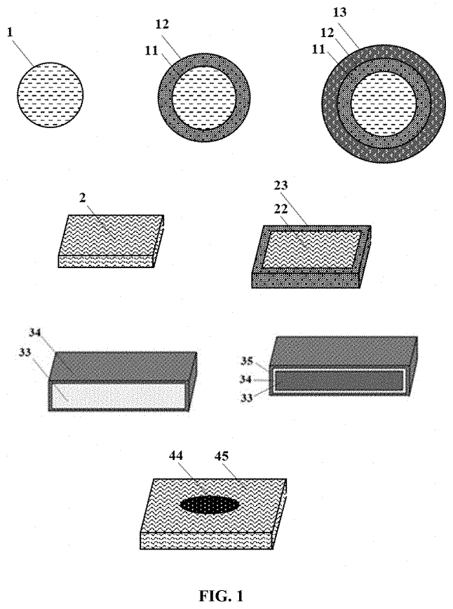

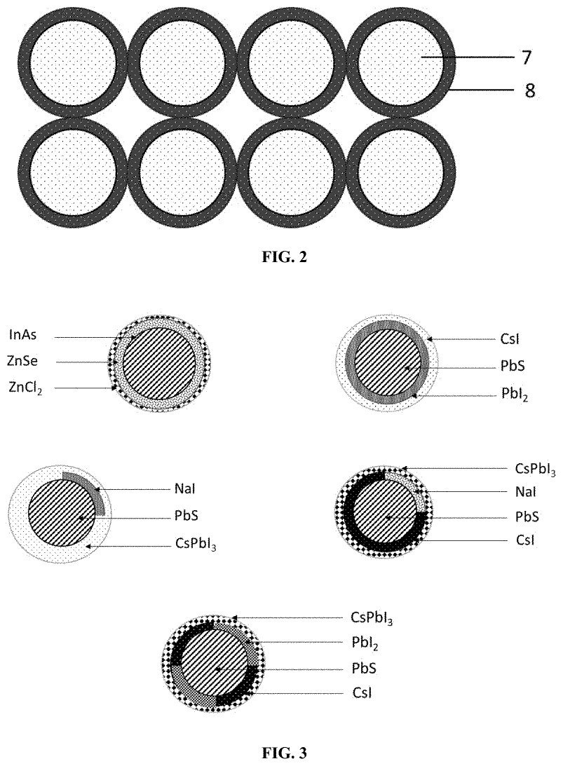

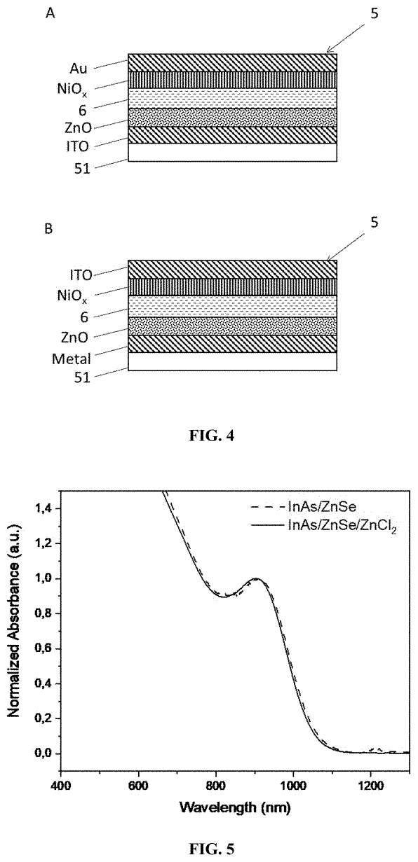

### EXAMPLES

The present invention is further illustrated by the following examples.

### Example 1: Ink Formulation—InAs/ZnSe Quantum Dots

In this example the ink comprises:
a colloidal dispersion comprising InAs/ZnSe quantum dots, dimethylformamide (DMF) (as a solvent) and butylamine (as a ligand); and
ZnCl₂ as the metal halide binder.

### InAs/ZnSe Quantum Dots Synthesis

In a three-neck flask, 400 mg of InCl₃ and 800 mg of ZnCl₂ are added in 15 mL of oleylamine. The solution is degassed at 115° C. for 1 hour. Under azote flow, 0.33 mL of As(NMe₂)₃ are injected. After the injection, the solution is heated at 190° C. for 30 min. 1.5 mL of P(NEt₂) are injected in the solution. The resulting mixture is heated at 230° C. for 1 h 15. ZnSe shell is formed by adding 800 mg of Zn(stear)₂ and slowly 1.1 mL of TOP-Se. The resulting solution is heated for 30 min. The temperature is cooled down.

The obtained InAs/ZnSe quantum dots are precipitated and dispersed in heptane.

Ligand Exchange with Metal Halide Binder

250 μL of formic acid are added in 1.35 mL of InAs/ZnSe quantum dots dispersion. After removing the heptane, precipitated quantum dots are washed.

InAs/ZnSe quantum dots are dispersed in a solution containing 250 mg of ZnCl₂ in 10 mL of DMF. Quantum dots are precipitated, dried under vacuum and dispersed in 250 μL of DMF and 15 μL of butylamine.

FIG. 5 shows the normalized absorption spectrum of InAs/ZnSe quantum dots and the ink comprising InAs/ZnSe quantum dots and ZnCl₂ binder. One can observed that the absorption spectrum was not changed, proving that InAs/ZnSe quantum dots were not damaged during the ink formulation.

### Example 2: Ink Formulation—PbS Quantum Dots

In this example the ink comprises:
a colloidal dispersion comprising PbS quantum dots, dimethylformamide (DMF) and acetonitrile (as a solvent) and butylamine (as a ligand); and
PbI₂ and CsI as the metal halide binders.

605 mg of lead iodide and 50 mg of sodium acetate are added in 10 mL of DMF. 10 mL of PbS quantum dots dispersed in heptane (12.5 mg·mL⁻¹) are added into DMF solution.

Sodium acetate promotes exchange from organic ligands to metal halide binder at the surface of PbS quantum dots.

After stirring, PbS quantum dots are transferred from the top heptane phase to the bottom DMF phase. After removing the heptane, PbS quantum dots solution is further washed.

PbS quantum dots are precipitated, dried under vacuum, then dispersed in 350 μL of DMF, in which 23 mg of cesium iodide were solubilized in advance. Then, 150 μL of acetonitrile and 10 μL of butylamine are added. The obtained ink is filtered (0.45 μm). The obtained ink comprises PbS quantum dots at a concentration of 250 mg·mL⁻¹.

### Deposition of the Ink on a Substrate

The ink is deposited on a clean substrate by spin coating (1 layer, 4 minutes at 1000 rpm).

Table 3 below lists ink compositions that have been prepared using PbS quantum dots as particles.

TABLE 3

| Quantum | | Metal | | | | | |
|---|---|---|---|---|---|---|---|
| dots | % wt | halide | % wt | Solvent | % wt | Ligands | % wt |
| PbS | 10.7 | PbI₂ | 26.5 | DMF/ACN 7/3 | 60.8 | Butylamine | 2 |
| PbS | 13.4 | PbI₂ + CsI | 22.5 | DMF/ACN 7/3 | 62.7 | Butylamine | 1.4 |
| PbS | 16.8 | PbI₂ + LiI | 18.3 | DMF/ACN 7/3 | 63.7 | Butylamine | 1.2 |
| PbS | 11.1 | PbI₂ + NaI | 24 | DMF/ACN 7/3 | 63.4 | Butylamine | 1.5 |
| PbS | 11.3 | PbI₂ + KI | 22.3 | DMF/ACN 7/3 | 65 | Butylamine | 1.4 |
| PbS | 16.9 | PbI₂ + CdI₂ | 20.5 | DMF/ACN 7/3 | 61.9 | Butylamine | 0.7 |
| PbS | 17 | PbI₂ + ZnI₂ | 18.7 | DMF/ACN 7/3 | 63.8 | Butylamine | 0.5 |
| PbS | 14.2 | PbI₂ + BiI₃ | 16.1 | DMF/ACN 7/3 | 69.7 | Butylamine | 1.8 |
| PbS | 10.2 | PbI₂ + SnI₂ | 28.5 | DMF/ACN 7/3 | 60.3 | Butylamine | 1 |

wherin DMF is dimethylformamide, and ACN is acetonitrile.

### Example 3: Ink Formulation—PbS Quantum Dots

In this example the ink comprises:
a colloidal dispersion comprising PbS quantum dots, dimethylformamide (DMF) and acetonitrile (as a solvent) and butylamine (as a ligand); and
PbI₂ and CsI as metal halide binders.

605 mg of lead iodide, 370 mg of cesium iodide and 50 mg of sodium acetate are added in 10 mL of DMF. 10 mL of PbS quantum dots dispersed in heptane (12.5 mg·mL⁻¹) are added into DMF solution.

After stirring, PbS quantum dots are transferred from the top heptane phase to the bottom DMF phase. After removing the heptane, PbS quantum dots solution is further washed.

PbS quantum dots are precipitated, dried under vacuum, then dispersed in 350 μL of DMF, 150 μL of acetonitrile and 10 μL of butylamine. The obtained ink is filtered (0.45 μm). The obtained ink comprises PbS quantum dots at a concentration of 250 mg·mL⁻¹.

Deposition of Ink onto a Substrate

The ink is deposited on a clean substrate by spin coating (1 layer, 4 minutes at 1000 rpm). The deposited ink is annealed at 150° C. for 30 min.

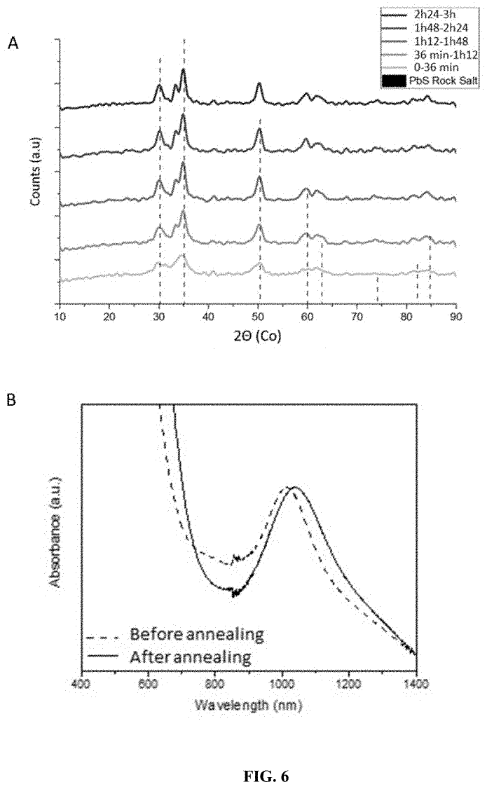

The crystallographic structure and the optical features given by quantum confinement are preserved after this thermal treatment (see FIGS. 6A and B).

### Test on Devices: Fabrication of IR Photodiode

i. Use pre-patterned ITO/glass substrate;
ii. Clean ITO substrate with detergent, EtOH, acetone, and 2-propanol;
iii. Warm substrate on hot plate at 110° C.;
iv. Spin-coat TiO₂ particle ink on the substrate at 5000 rpm for 30 seconds;
v. Anneal on a hot plate at 450° C. for 30 minutes;
vi. Cool down the substrate before next ink deposition;
vii. Deposit the PbS ink;
viii. Put the sample in vacuum in a thermal evaporation system;
ix. Deposit 10 nm of a MoO₃ thin film at 0.2 nm/second via thermal evaporation technique;
x. Deposit 80 nm of an Au thin film at 0.2 nm/second via thermal evaporation technique to form the top electrode through a suitable shadow mask;
xi. Obtain the final IR sensor based on multi-dot thin film;
xii. Heat device to 150° C. for 1 to 3 hours.

The characterization includes I-V measurement in dark and under illumination conditions to extract the device performance such as the quantum efficiency and dark current;

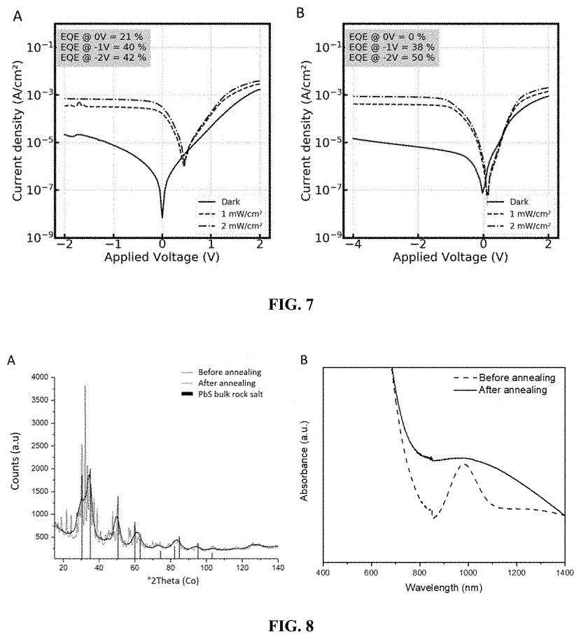

In this example, the results showed that the performance exhibit no degradation after annealing (see FIGS. 7A and 6B).

### Time Response

The temporal response of the device at high frequency is also characterized. The measurement is carried out by using a nanosecond pulsed laser source centered at 940 nm to illuminate the device and by using a 1 GHz high-speed transimpedance amplifier coupled with a 2 GHz high-bandwidth oscilloscope to measure the electronic response of the photodiode. In this example, the fabricated photodiode is polarized at −1V and is characterized with a 60 ns pulsed laser at 0.5 MHz frequency, with a pulsed power of 0.1 W/cm². The temporal response of the device is measured before and after thermal treatment at 150° C. for 3 hours. The result shows that the fabricated device has a fast response performance with a rise time (tᵣᵢₛₑ) of about 20 ns, and a fall time (t_{fall}) less than 250 ns (with tᵣᵢₛₑ and t_{fall} define by the duration to reach 20% and 80% of the signal). Also, the response time shows no degradation after thermal treatment, indicating good thermal stability of the device and the photosensitive film. The measured response in this example is however limited by the capacitance of the fabricated device (with an active area of 0.45 mm²). This suggests that the temporal response of the device employing the photosensitive film in this invention could be even faster (at least down to few ns) if the active area of the device is reduced.

The following comparative examples demonstrate that the use of the ink of this invention into devices improve thermal stability of the photosensitive film.

### Comparative Example 1: Using Ammonium Iodide as Ligands

450 mg of lead iodide are added in 10 mL of DMF. 10 mL of PbS quantum dots dispersed in heptane (12.5 mg·mL⁻¹) are added into DMF solution.

After stirring, PbS quantum dots are transferred from the top octane phase to the bottom DMF phase. After removing the heptane, PbS quantum dots solution is further washed.

PbS quantum dots are precipitated, dried under vacuum, then dispersed in 350 μL of DMF, 150 μL of acetonitrile and 10 μL of butylamine. The obtained ink is filtered (0.45 μm). The obtained ink comprises PbS quantum dots at a concentration of 250 mg·mL⁻¹.

Deposition of Ink onto a Substrate

Same as Example 3

FIG. 8A, the emergence of new phase (Pb₅S₂I) is observed after annealing, proving that the PbS core structure has been modified during annealing. Moreover, optical features of the deposited ink are degraded after the thermal treatment (see FIG. 8B).

### Test on Devices: Fabrication of IR Photodiode

Same as Example 3

The photocurrent is degraded after the annealing. This results from PbS core structure modification and deterioration during annealing.

### Comparative Example 2: Using Lead Halides as Ligands

575 mg of lead iodide, 91 mg of lead bromide and 40 mg of sodium acetate are added in 10 mL of DMF. 10 mL of PbS quantum dots dispersed in heptane (12.5 mg·mL-1) are added into DMF solution.

After stirring, PbS quantum dots are transferred from the top heptane phase to the bottom DMF phase. After removing the heptane, QD solution is further washed.

PbS quantum dots are precipitated, dried under vacuum, then dispersed in 350 μL of DMF, 150 μL of acetonitrile and 10 μL of butylamine. The obtained ink is filtered (0.45 μm). The obtained ink comprises PbS quantum dots at a concentration of 250 mg·mL⁻¹.

Deposition of Ink onto a Substrate

Same as Example 3

### Test on Devices: Fabrication of IR Photodiode

Same as Example 3

The performances of the device are degraded after the annealing. This results from PbS core structure modification and deterioration during annealing.

### Comparative Example 3: Core/Shell PbS/CdS Quantum Dots

In a 100 mL three neck flask is introduced 22 mL of Cd(OA)₂ (0.35 M/ODE). The solution is degassed under vacuum at 110° C. during 1 h. Under azote flow, the temperature is set to 70° C. A solution of PbS quantum dots (50 mg·mL⁻¹) diluted with 6 mL of toluene are quickly injected in Cd(OAc)₂ solution. After 20 min of heating, 15 mL of heptane are added to quench the reaction.

PbS/CdS quantum dots are precipitated and dispersed in 6 mL of heptane.

Deposition of Ink onto a Substrate

Same as Example 3

The crystallographic structure is preserved during the annealing step. However, a blueshift is observed after the thermal treatment. It is the consequence of diffusion of Cd atoms from the shell in PbS core. Therefore, PbS/CdS don't exhibit thermal stability.

### REFERENCES

1—Core
11—Nanosphere core
12—Shell covering partially or totally a nanosphere core
13—Shell covering partially or totally a core/shell particle
2—Nanoplate
22—Nanoplate core
23—Crown
33—Nanoplate core
34—Shell covering partially or totally a nanoplate core
35—Shell covering partially or totally a core/shell particle
44—Nanosphere core
45—Shell covering partially or totally a nanosphere core
5—Device
51—Substrate
6—Photosensitive film
7—Particle
8—Metal halide binder

1-15. (canceled)

16. An ink comprising:
a) at least one colloidal dispersion of particles, said particles comprising a material of formula
MₓQ_{y}E_{z}A_{w} (I)
wherein:
M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
E is selected from the group consisting of O, S, Se, Te, C, N, P, As, Sb, F, Cl, Br, I, F, or a mixture thereof; and
A is selected from the group consisting of O, S, Se, Te, C, N, P, As, Sb, F, Cl, Br, I, F, or a mixture thereof;
x, y, z and w are independently a decimal number from 0 to 5; x, y, z and w are not simultaneously equal to 0; x and y are not simultaneously equal to 0; z and w may not be simultaneously equal to 0;
wherein the colloidal dispersion of particles further comprises at least one solvent and at least one ligand;
b) at least one metal halide binder soluble in the colloidal dispersion a); wherein:
the amount of particles in the ink is ranging from 1 to 40 wt % based on the total weight of the ink;
the amount of solvent in the ink is ranging from 25 to 97 wt % based on the total weight of the ink;
the amount of ligand in the ink is ranging from 0.1 to 8 wt % based on the total weight of the ink; and
the amount of metal halide binder is ranging from 1 to 60% based on the total weight of the ink.

17. The ink according to claim 16, wherein the particles are semiconductor particles.

18. The ink according to claim 17, wherein the semiconductor particles are quantum dots.

19. The ink according to claim 18, wherein the quantum dots are core/shell quantum dots, the core comprising a different material from the shell.

20. The ink according to claim 16, wherein the amount of particles in the ink is ranging from 1 to 40 wt %, based on the total weight of the ink.

21. The ink according to claim 16, wherein the metal halide is selected from the group of ZnX₂, PbX₂, CdX₂, SnX₂, HgX₂, BiX₃, CsX, NaX, KX, LiX, CsPbX₃ et HC(NH₂)₂PbX₃, CH₃NH₃PbX₃, or a mixture thereof, wherein X is selected from Cl, Br, I, F or a mixture thereof.

22. The ink according to claim 16, wherein the colloidal dispersion of particles comprises at least one polar solvent selected from the group comprising formamide, dimethylformamide, N-methylformamide, 1,2-dichlorobenzene, 1,2-dichloroethane, 1,4-dichlorobenzene, propylene carbonate and N-methyl-2-pyrrolidone, dimethyl sulfoxide, 2,6 difluoropyridine, N,N dimethylacetamide, γ-butyrolactone, dimethylpropyleneurea, triethylphosphate, trimethylphosphate, dimethylethyleneurea, tetramethylurea, diethylformamide, o-Chloroaniline, dibutylsulfoxide, diethylacetamide, or a mixture thereof.

23. A method for preparing a light-sensitive material comprises the steps of:
a) depositing an ink according to claim 16 onto a substrate;
b) annealing deposited ink.

24. The method according to claim 23, wherein the deposited ink is annealed at a temperature ranging from 50° C. to 250° C.

25. The method according to claim 23, wherein the deposited ink is annealed during a period of time ranging from 10 minutes to 5 hours.

26. A light-sensitive material obtainable by the method according to claim 23.

27. The light-sensitive material according to claim 26, wherein said material is a continuous electrically conductive film comprising particles bound by a metal halide.

28. A device comprising at least one light-sensitive material according to claim 26.

29. The device according to claim 28, wherein said device comprises:
at least one substrate;
at least one electronic contact layer;
at least one electron transport layer; and
at least one photoactive layer comprising at least one light-sensitive material according to claim 26;
wherein said device has a vertical geometry.
